(19) United States
(12) Patent Application Publication
(10) Pub. No.: US 2026/0239837 A1
(43) Pub. Date: Aug. 13, 2026

(54) ELECTRONIC APPARATUS

(71) Applicant: Samsung Display Co., Ltd., Yongin-si (KR)

(72) Inventors: KWANGSOO LEE, Yongin-si (KR); KIWOOK KIM, Yongin-si (KR)

(21) Appl. No.: 19/424,443

(22) Filed: Dec. 18, 2025

(30) Foreign Application Priority Data
Feb. 11, 2025 (KR) 10-2025-0017572

(51) Int. Cl. H10K 59/131; H10K 59/12; H10K 59/122; H10K 59/80

(52) U.S. Cl. CPC H10K 59/131; H10K 59/1201; H10K 59/122; H10K 59/873

(57) ABSTRACT

An electronic apparatus includes a light-emitting element layer connected to a driving element layer including a signal line connected to a pixel driving part, the signal line including a fan-out line which defines a pad part at the end thereof, an organic film and an inorganic film, an encapsulation layer on the light-emitting element layer, the encapsulation layer including an inorganic encapsulation layer, and a bank spaced apart from the light-emitting element layer in a planar direction, the bank including an organic layer having a side surface closest to the light-emitting element layer and including inclined parts having different angles of inclination in a cross-sectional view. A stepped region is defined between the pad part and the light-emitting element layer, the stepped region including the first side surface of the bank. A first part of the fan-out line overlaps the stepped region and is parallel to the planar direction.

This patent application claims priority to Korean Patent Application No. 10-2025-0017572, filed on Feb. 11, 2025, and all the benefits accruing therefrom under 35 U.S.C. § 119, the entire contents of which are hereby incorporated by reference.

### BACKGROUND

### (1) Field

The present disclosure herein relates to an electronic apparatus. More particularly, the present disclosure relates to an electronic apparatus including an optical film.

### (2) Description of the Related Art

Various display panels used in multimedia electronic apparatuses such as a television, a mobile phone, a tablet computer, a navigation unit and a game console are being developed. A display panel may include a display region in which an image is displayed, and a peripheral region which is a non-display region surrounding the display region. Pixels, which are minimum units for displaying an image, may be disposed in the display region. The pixels may each include a pixel circuit and a light-emitting element connected to the pixel circuit. Fan-out lines for providing signals and voltages to the pixels may be disposed in the peripheral region.

### SUMMARY

A dam part or a bank for preventing overflow of an organic material and/or an inorganic material in a process of forming an encapsulation layer which covers a light-emitting element within an electronic apparatus, may be formed in the peripheral region. In a process of manufacturing the electronic apparatus, a crack may occur in the encapsulation layer positioned on a side surface of the dam part or bank. When moisture is introduced from the outside of the electronic apparatus due to the crack, fan-out lines disposed in the peripheral region for providing signals and voltages to pixels in the display area, may be corroded.

The present disclosure provides an electronic apparatus with improved process reliability.

An embodiment of the invention provides an electronic apparatus including a substrate including a display region and a peripheral region adjacent to the display region, a light-emitting element layer disposed in the display region and including a pixel-defining film having a plurality of openings defined therein and a plurality of light-emitting elements respectively disposed in the openings and configured to emit light, a driving element layer disposed between the base substrate and the light-emitting element layer and including a plurality of pixel driving parts respectively connected to the light-emitting elements, a plurality of signal lines respectively connected to the pixel driving parts, at least one organic film, and at least one inorganic film, an encapsulation layer disposed on the light-emitting element layer and including at least one inorganic encapsulation layer, and a bank disposed in the peripheral region, extending along a first direction, spaced apart from the display region in a second direction crossing the first direction, and including an organic layer, where the signal lines include a plurality of fan-out lines disposed in the peripheral region and having a pad part defined on the other end thereof, the peripheral region includes a stepped region defined between the pad part and the display region, a first side surface, of the bank, overlapping the stepped region includes at least two inclined parts having different angles of inclination in a cross-sectional view, and a first part, of each of the fan-out lines, overlapping the stepped region is parallel to the second direction.

In an embodiment, the electronic apparatus according to an embodiment of the invention may further include a driving chip connected to the pad part.

In an embodiment, the electronic apparatus according to an embodiment of the invention may further include a circuit board connected to the pad part.

In an embodiment, the angle of inclination may be less than about 90 degrees.

In an embodiment, the bank may include an organic layer which is the same as at least one of the at least one organic film of the driving element layer and the pixel-defining film.

In an embodiment, the electronic apparatus according to an embodiment of the invention may further include an optical film which is disposed on the encapsulation layer and covers the stepped region, where the bank may overlap, in a plan view, an end of the optical film.

In an embodiment, the inorganic encapsulation layer may cover the stepped region, and the optical film may cover an end of the inorganic encapsulation layer.

In an embodiment, each of the fan-out lines may further include a second part extending from one end of the first part toward the display region and inclined with respect to the first part; and a third part extending from the other end of the first part toward the pad part and inclined with respect to the first part.

In an embodiment, the bank may have a frame shape surrounding the display region.

In an embodiment, the first side surface may have at least one curved surface.

In an embodiment of the invention, an electronic apparatus includes a display panel and an optical film disposed on the display panel, where the display panel includes a substrate, an inorganic layer disposed on the substrate, a fan-out line disposed between the substrate and the inorganic layer, an organic light-emitting element disposed on the inorganic layer and including an anode, a light-emitting layer, and a cathode, a bank disposed on the inorganic layer, extending along a first direction in a plan view, spaced apart from the organic light-emitting element in a second direction crossing the first direction, and overlapping the fan-out line, and an encapsulation layer covering the organic light-emitting element and including a first inorganic encapsulation layer, an organic encapsulation layer, and a second inorganic encapsulation layer, an end of the optical film overlaps the bank in a plan view, a first side surface, of the bank, facing the organic light-emitting element includes at least two inclined parts having different angles of inclination in a cross-sectional view, and a first part, of the fan-out line, overlapping the first side surface is parallel to the second direction.

In an embodiment, each of the angles of inclination may be less than about 90 degrees.

In an embodiment, the bank may include a plurality of organic layers, and the first side surface may be defined by side surfaces of at least two organic layers among the organic layers.

In an embodiment, the bank may include a plurality of organic layers, and the first side surface may be defined by any one organic layer among the organic layers.

In an embodiment, the organic layers may include a first organic layer, a second organic layer, and a third organic layer which are sequentially stacked, the second organic layer may cover the first organic layer, and the third organic layer may be spaced apart from the first organic layer and cover the second organic layer, and the first side surface may be defined by the third organic layer.

In an embodiment, the organic layers may include a first organic layer, a second organic layer, and a third organic layer which are sequentially stacked, and the second organic layer may expose a side surface of the first organic layer, and the third organic layer may cover the exposed side surface of the second organic layer.

In an embodiment, a second side surface, of the bank, oriented in an opposite direction to the first side surface may have a shape different from that of the first side surface.

In an embodiment, on the fan-out line, at least one of the first inorganic encapsulation layer and the second inorganic encapsulation layer may be in contact with at least a portion of the inorganic layer.

In an embodiment, the fan-out line may further include a second part extending from one end of the first part and inclined with respect to the first direction and the second direction.

In an embodiment, the fan-out line may further include a third part extending from the other end of the first part and overlapping the end of the optical film.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an electronic apparatus according to an embodiment of the invention;

FIG. 2 is an exploded perspective view of an electronic apparatus according to an embodiment of the invention;

FIG. 3A is a cross-sectional view of an electronic apparatus according to an embodiment of the invention;

FIG. 3B is a cross-sectional view of a display module according to an embodiment of the invention;

FIG. 4A is a plan view of a display panel according to an embodiment of the invention;

FIG. 4B is an equivalent circuit diagram of a pixel according to an embodiment of the invention;

FIGS. 5A and 5B are each an enlarged cross-sectional view of one region of a display panel according to an embodiment of the invention;

FIG. 6 is a schematic view of a part of manufacturing steps of a display panel according to an embodiment of the invention;

FIGS. 7A and 7B are each a schematic cross-sectional view of a bank according to an embodiment of the invention;

FIGS. 8A and 8B are each a plan view of an electronic apparatus according to an embodiment of the invention;

FIG. 9 is a plan view illustrating a partial region of a display panel according t an embodiment of the invention;

FIG. 10A is a plan view illustrating a portion of a display panel according to an embodiment of the invention;

FIG. 10B is a cross-sectional view, of a display panel, illustrating a portion of region corresponding to FIG. 10A;

FIGS. 11A and 11B are each a plan view illustrating a part of manufacturing steps of a display panel according to an embodiment of the invention;

FIG. 12 is a block diagram of an electronic apparatus according to an embodiment; and

FIG. 13 illustrates schematic views of electronic apparatuses according to various embodiments.

### DETAILED DESCRIPTION

In this specification, it will be understood that when an element (or a region, a layer, a portion, or the like) is referred to as being related to another element such as being “on”, “connected to” or “coupled to” another element, it may be directly disposed on, connected to, or coupled to the other element, or other elements may be disposed therebetween. In contrast, when an element (or a region, a layer, a portion, or the like) is referred to as being related to another element such as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents.

As used herein, the term “and/or” includes any and all combinations of one or more of the associated listed elements. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.”

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the invention. Similarly, a second element could be termed a first element.

In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention are described with reference to the drawings.

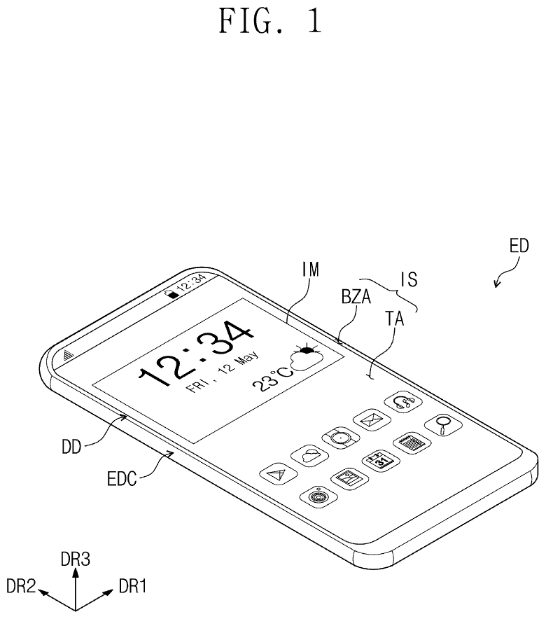

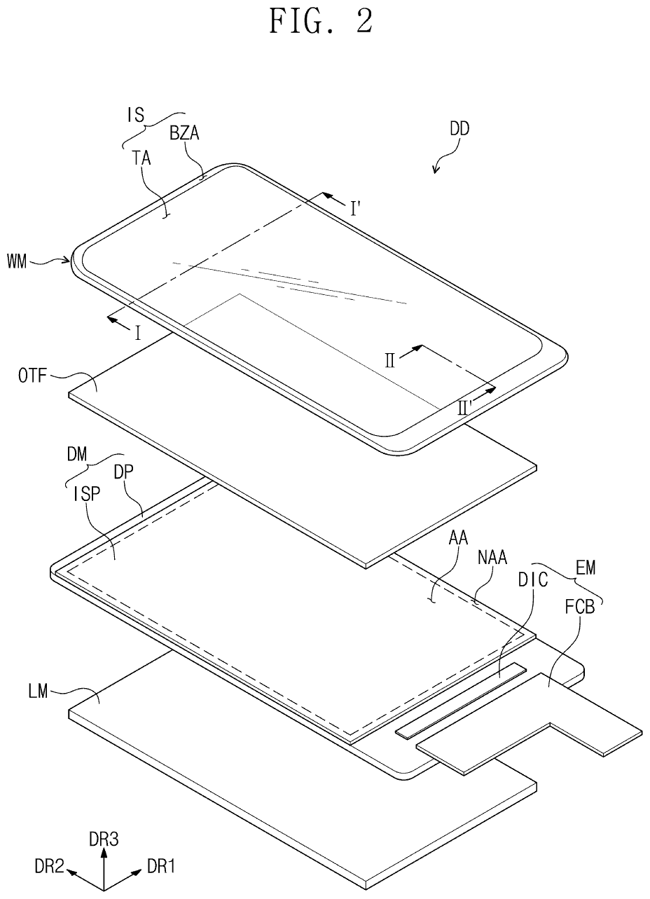

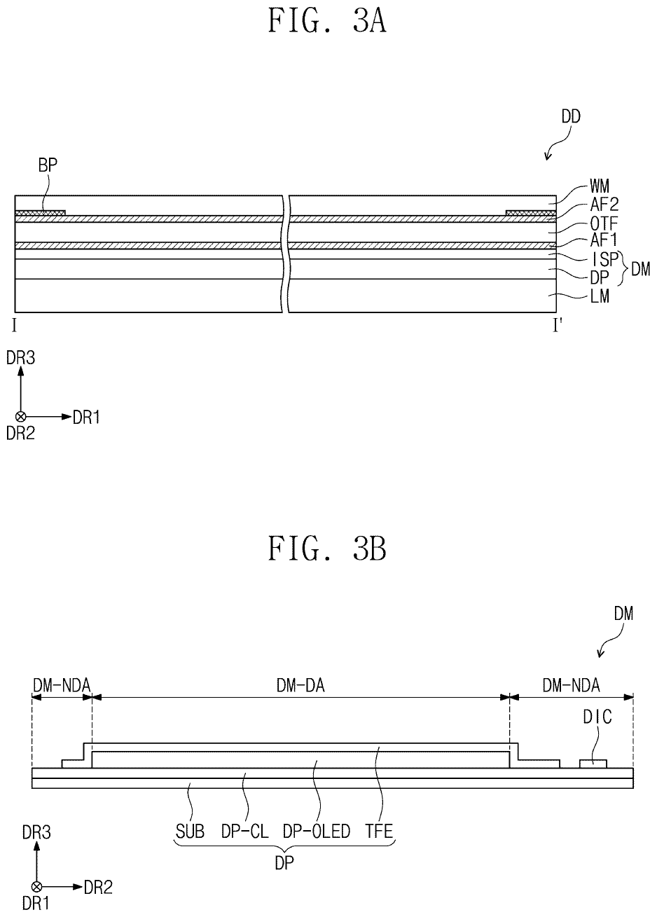

FIG. 1 is a perspective view of an electronic apparatus ED according to an embodiment of the invention. FIG. 2 is an exploded perspective view of an electronic apparatus ED according to an embodiment of the invention. FIG. 3A is a cross-sectional view of an electronic apparatus ED according to an embodiment of the invention. FIG. 3B is a cross-sectional view of a display module DM according to an embodiment of the invention.

An electronic apparatus ED may be activated in response to an electrical signal. The electronic apparatus ED may include various embodiments. For example, the electronic apparatus ED may be or include a display device DD such as a smart watch, a tablet computer, a laptop computer, a computer and a smart television.

The electronic apparatus ED may display an image IM on a display surface IS which is parallel to a plane defined by the first direction DR1 and a second direction DR2 crossing each other. The image IM may be viewed in the third direction DR3 crossing each of the first direction DR1 and the second direction DR2. The display surface IS on which the image IM is displayed may correspond to a front surface of the electronic apparatus ED. The image IM may include a static image as well as a dynamic image.

In this embodiment, a front surface and a rear surface may be opposed to each other in the third direction DR3, and a normal direction of each of the front surface and the rear surface may be parallel to the third direction DR3. A separation distance between the front surface and the rear surface in the third direction DR3 may correspond to a thickness of the electronic apparatus ED in the third direction DR3 (e.g., a thickness direction or a plan view direction). Meanwhile, directions indicated by the first to third directions DR1, DR2, and DR3 have relative concepts, and may thus be changed to other directions.

The electronic apparatus ED may detect an external input applied from the outside (e.g., outside of the electronic apparatus ED, outside of the display device DD, etc.). The external input may include various types of inputs provided from outside of the electronic apparatus ED, such as by an input tool. For example, the external input may include not only a touch by a part of a body such as a user's hand, but also an external input applied by an input tool proximate to or adjacent to, within a predetermined distance, the electronic apparatus ED (for example, hovering). In addition, the external input may have various types such as force, pressure, temperature, or light.

The display surface IS of the electronic apparatus ED may be divided into a transmission region TA and a bezel region BZA. The transmission region TA may be a region in which the image IM is displayed. A user views the image IM through the transmission region TA. In this embodiment, the transmission region TA is illustrated as a quadrilateral shape with rounded vertices in the plan view. However, this is illustrated as an example. The transmission region TA may have various shapes and is not limited to any one embodiment.

The bezel region BZA is adjacent to the transmission region TA. The bezel region BZA may have a predetermined color. The bezel region BZA may surround the transmission region TA in the plan view. Accordingly, a planar shape of the transmission region TA may be defined substantially by the bezel region BZA. However, this is illustrated as an example, and the bezel region BZA may be disposed adjacent to only one side of the transmission region TA, or may be omitted. The electronic apparatus ED according to an embodiment of the invention may include various embodiments, and is not limited to any one embodiment.

The electronic apparatus ED may include a display device DD and an external case EDC (a housing). The display device DD may include a window WM, a display module DM, a driving module EM, an optical film OTF, and a lower module LM. The display module DM may include a display panel DP and an input sensor ISP which is disposed on the display panel DP. The display panel DP generates the image IM, and the input sensor ISP acquires coordinate information of an external input (for example, a touch event).

The window WM may be composed of a transparent material which allows an image, light, etc. to be output. For example, the window WM may be composed of glass, sapphire, plastic, or the like. The window WM is illustrated as a single layer, but is not limited thereto, and may include a plurality of layers. Meanwhile, although not illustrated, the bezel region BZA of the display device DD described above may be defined substantially by a bezel pattern BP of the window WM. The bezel pattern BP may be formed by depositing or printing, on the window WM, a material with a low light transmittance, for example, color ink, a resin, a conductive pattern, etc.

The display module DM may display an image IM in response to an electrical signal and transmit/receive information about an external input. The display module DM may be defined as an active region AA and a peripheral region NAA. The active region AA may be defined as a region or planar area in which the image provided by the display module DM is output from the electronic apparatus ED.

The peripheral region NAA is adjacent to the active region AA. For example, the peripheral region NAA may surround the active region AA. However, this is illustrated as an example, and the peripheral region NAA may be defined in various shapes, and is not limited to any one embodiment. According to an embodiment, the active region AA of the display module DM may correspond to at least a portion of the transmission region TA.

The display module DM may include the display panel DP and the input sensor ISP. The display panel DP according to an embodiment of the invention may be an emissive display panel, but is not particularly limited thereto. For example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, and the like. Hereinafter, the display panel DP is described as an organic light-emitting display panel.

The display panel DP includes a base layer SUB and a circuit element layer DP-CL, a display element layer DP-OLED, and a thin-film encapsulation layer TFE which are disposed on the base layer SUB. The display panel DP may be an emissive display panel, and is not particularly limited. For example, the display panel DP may be an organic light-emitting display panel or a quantum dot light-emitting display panel. A light-emitting layer of the organic light-emitting display panel includes an organic light-emitting material. A light-emitting layer of the quantum dot light-emitting display panel includes quantum dots and quantum rods. Hereinafter, the display panel DP is described as an organic light-emitting display panel. Although not illustrated separately, the display panel DP may further include functional layers such as an anti-reflection layer and a refractive index control layer.

The base layer SUB may include at least one plastic film. The base layer SUB may be a flexible substrate and include a plastic substrate, a glass substrate, a metal substrate, an organic/inorganic composite material substrate, or the like.

The circuit element layer DP-CL includes at least one intermediate insulating layer and a circuit element. The intermediate insulating layer includes at least one intermediate inorganic film and at least one intermediate organic film. The circuit element includes signal lines, a driving circuit of a pixel, etc. This will be described in detail later.

The display element layer DP-OLED (or light-emitting element layer DP-OLED) includes at least organic light-emitting diodes. The display element layer DP-OLED may further include an organic film such as a pixel-defining film. The display region DM-DA described hereinafter may correspond to a region or planar area in which light emitted from the organic light-emitting diode is displayed, and a non-display region DM-NDA may correspond to a region in which light is not displayed, that is, a region in which the organic light-emitting diode is not disposed.

The thin-film encapsulation layer TFE (or an encapsulation layer TFE) seals the display element layer DP-OLED. The thin-film encapsulation layer TFE includes at least one inorganic film (hereinafter, an inorganic encapsulation film). The thin-film encapsulation layer TFE may further include at least one organic film (hereinafter, an organic encapsulation film). The inorganic encapsulation film protects the display element layer DP-OLED from moisture/oxygen, and the organic encapsulation film protects the display element layer DP-OLED from foreign substances such as dust particles. The inorganic encapsulation film may include a silicon nitride layer, a silicon oxynitride layer and a silicon oxide layer, a titanium oxide layer, an aluminum oxide layer, or the like. The organic encapsulation film may include an acrylic organic layer, and is not limited thereto.

The input sensor ISP as an input sensing layer may be ‘directly disposed’ on the display panel DP. According to an embodiment of the invention, the input sensor ISP may be formed on the display panel DP through a continuous process. That is, when the input sensor ISP is directly disposed on the display panel DP, an adhesive film for bonding the input sensor ISP and the display panel DP may be omitted. Here, the ‘directly disposed’ elements or layers may form an interface therebetween. In addition, the input sensor ISP may be omitted in the display module DM according to an embodiment of the invention.

The optical film OTF reduces a reflectance for external light incident from above the window WM. The optical film OTF according to an embodiment of the invention may be a retardation film, a polarization film, or a film with other optical effects. The optical film OTF may further include a protection film disposed on an upper portion or a lower portion.

The optical film OTF may be disposed on the input sensor ISP. That is, the optical film OTF may be disposed between the input sensor ISP and the window WM. The input sensor ISP, the optical film OTF, and the window WM may be bonded to each other by an adhesive layer.

A first adhesive layer AF1 is disposed between the input sensor ISP and the optical film OTF, and a second adhesive layer AF2 is disposed between the optical film OTF and the window WM. Accordingly, the optical film OTF may be bonded to the input sensor ISP by the first adhesive layer AF1, and the window WM may be bonded to the optical film OTF by the second adhesive layer AF2.

As an example of the invention, the adhesive layers AF1 and AF2 may each include an optically clear adhesive film (OCA). However, a material of each of the adhesive layers AF1 and AF2 is not limited thereto, and may include a typical adhesive or detachable adhesive. For example, the adhesive layers AF1 and AF2 may each include a pressure sensitive adhesive (PSA), an optical clear adhesive (OCA), or an optical clear resin (OCR).

Meanwhile, this is illustrated as an example, and the display device DD according to an embodiment of the invention may further include an anti-reflection layer (not shown) directly disposed on the display module DM. The anti-reflection layer may be directly disposed on the input sensor ISP or may be disposed between the input sensor and the display panel DP. The anti-reflection layer may include a black matrix layer in which a plurality of openings are defined, or include a color filter layer. In this case, the optical film OTF and the first adhesive layer AF1 may be omitted. In addition, a functional layer which performs other functions, for example, a protection layer and the like, may be further disposed between the display module DM and the window WM in addition to the optical film OTF.

The driving module EM as a driver may control driving of the display module DM. The driving module EM may be connected to pads of the display module DM, which are not illustrated, to be electrically connected to the display module DM at the pads. The driving module EM may include a circuit board FCB and a driving chip DIC. The circuit board FCB may be electrically connected to the display panel DP, such as at a portion of the non-display region DM-NDA. Alternatively, the circuit board FCB may be electrically connected to the display panel DP and the input sensor ISP.

The circuit board FCB may be bonded to the display module DM through a bonding process. The circuit board FCB may be electrically connected to the display module DM by an anisotropic conductive adhesive layer. The driving chip DIC may be mounted in the non-display region DM-NDA of the display module DM. The driving chip DIC may include driving circuits, for example, a data driving circuit, for driving pixels of the display panel DP.

The circuit board FCB may include a plurality of driving elements. The driving element may include a circuit part for converting a signal input from the outside into a signal required for the driving chip DIC or a signal required for driving the display module DM. Alternatively, the circuit board FCB may include a ground line for discharging static electricity introduced to the circuit board FCB or the display module DM. Alternatively, a separate rigid circuit board may be provided, and the circuit board FCB may only include signal lines for electrical connection between the circuit board and the display module DM. The circuit board FCB may include various electrical elements, and is not limited to any one embodiment.

In this embodiment, when electronic apparatus ED includes the circuit board FCB accommodated in the external case EDC, at least a portion of the circuit board FCB may be bent to be disposed under the display module DM. Alternatively, at least a portion of the display module DM may be bent, and thus the circuit board FCB may be disposed under the display module DM. Alternatively, when all of the driving elements included in the circuit board FCB are mounted on the display module DM, the circuit board FCB may be omitted.

The lower module LM is disposed on a rear surface of the display module DM. Since the lower module LM is disposed on the rear surface of the display module DM, impact resistance of the display device DD may be improved. The lower module LM may be fixed to the rear surface of the display module DM by an adhesive layer.

The external case EDC may be coupled to the window WM and define an exterior of the electronic apparatus ED. The external case EDC accommodates the display device DD. The external case EDC absorbs an impact applied from the outside and prevents foreign substances/moisture and the like from infiltrating into the electronic apparatus ED to protect components accommodated in the external case EDC. Meanwhile, as an example of the invention, the external case EDC may be provided in a form in which a plurality of accommodation members are coupled.

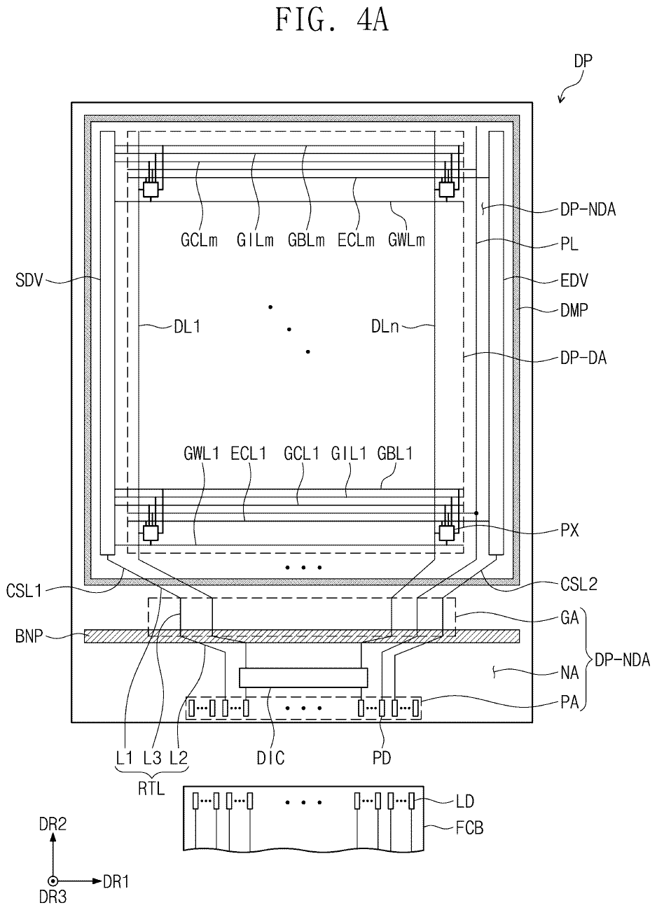

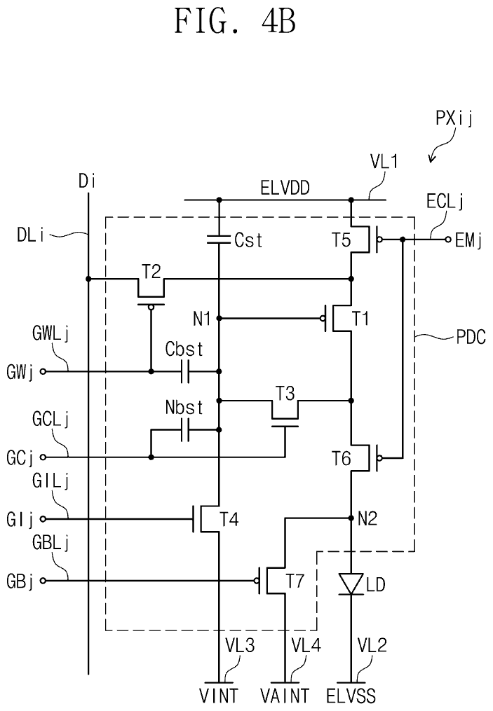

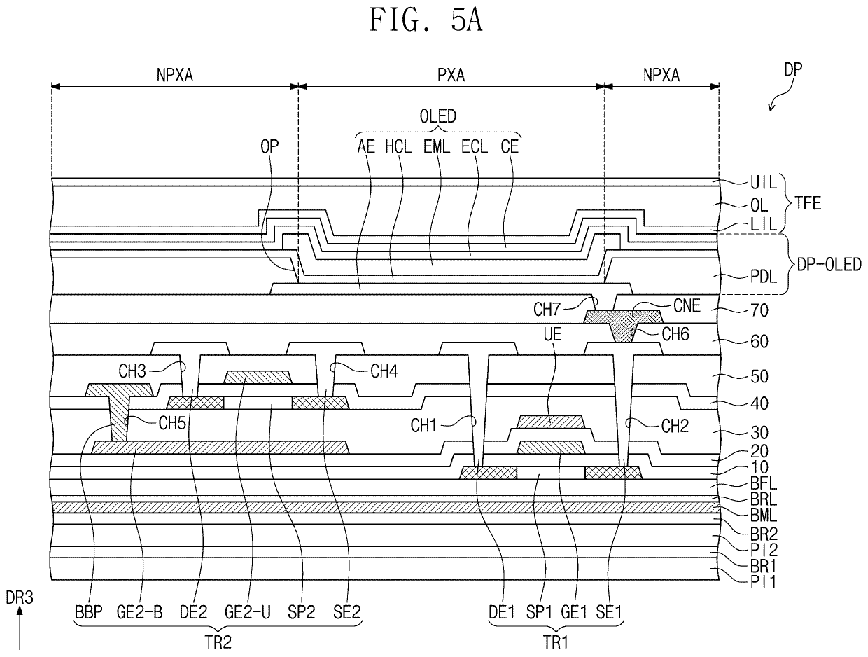

FIG. 4A is a plan view of a display panel DP according to an embodiment of th invention. FIG. 4B is an equivalent circuit diagram of a pixel PX according to an embodiment of the invention. Hereinafter, the invention will be described with reference to FIGS. 4A and 4B. Meanwhile, components which are the same as the components described with reference to FIGS. 1 to 3B will be denoted as the same reference numerals or symbols, and duplicated descriptions will be omitted.

Referring to FIG. 4A, a display region DP-DA and a non-display region DP-NDA around the display region DP-DA may be defined in a display panel DP. The display region DP-DA and the non-display region DP-NDA may be distinguished by whether a pixel PX is disposed therein or is absent therefrom. The pixel PX is disposed in the display region DP-DA. A scan driving part SDV, a data driving part, and an emission driving part EDV may be disposed in the non-display region DP-NDA. The data driving part may be a portion of a circuit configured in a driving chip DIC. The display region DP-DA and the non-display region DP-NDA of the display panel DP respectively correspond to the display region DM-DA and the non-display region DM-NDA of the display module DM illustrated in FIG. 3B. Meanwhile, the display region DP-DA and the non-display region DP-NDA of the display panel DP do not necessarily have to be the same area, size, location, etc. as and the display region DM-DA and the non-display region DM-NDA of the display module DM, and may be changed according to the structure/design of the display panel DP.

The display panel DP may include pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a driving voltage line PL, and a pad PD provided in plural to define a plurality of pads PD. Here, ‘m’ and ‘n’ are natural numbers greater than or equal to 2. Within the Figures and the text of the disclosure, a reference number indicating a singular form of an element may also be used to reference a plurality of the element.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 and be electrically connected to the scan driving part SDV. The data lines DL1 to DLn may extend in the second direction DR2 and be electrically connected to the driving chip DIC via a bending region BA. The emission control lines ECL1 to ECLm may extend in the first direction DR1 and be electrically connected to the emission driving part EDV.

The driving voltage line PL may include a portion extending in the second direction DR2 and a portion inclined with respect to the second direction DR2. The driving voltage line PL may provide a driving voltage to the pixels PX.

FIG. 4B illustrates an equivalent circuit diagram of one pixel PXij of the plurality of pixels PX as an example. Since each of the plurality of pixels PX has the same circuit configuration, by describing a circuit configuration of the pixel PXij, a detailed description of the rest of the pixels PX will be omitted.

The pixel PXij is connected to an i-th data line DLi of the data lines DL1 to DLn, a j-th initialization scan line GILj of the initialization scan lines GIL1 to GILm, a j-th compensation scan line GCLj of the compensation scan lines GCL1 to GCLm, a j-th write scan line GWLj of the write scan lines GWL1 to GWLm, a j-th black scan line GBLj of the black scan lines GBL1 to GBLm, a j-th emission control line ECLj of the emission control lines ECL1 to ECLm, first and second driving voltage lines VL1 and VL2, and first and second initialization voltage lines VL3 and VL4. Here, ‘’' is an integer equal to or greater than 1 and equal to or less than ‘n,’ and ‘j’ is an integer equal to or greater than 1 and equal to or less than ‘m.’

The pixel PXij includes a light-emitting element LD and a pixel circuit PDC. The light-emitting element LD may be a light-emitting diode. As an example of the invention, the light-emitting element LD may be an organic light-emitting diode including an organic light-emitting layer, but is not particularly limited thereto. The pixel circuit PDC may be electrically connected to the light-emitting element LD and control the amount of (electrical) current flowing in the light-emitting element LD in response to a data signal Di. The light-emitting element LD may emit light having a predetermined luminance corresponding to the amount of current provided from the pixel circuit PDC.

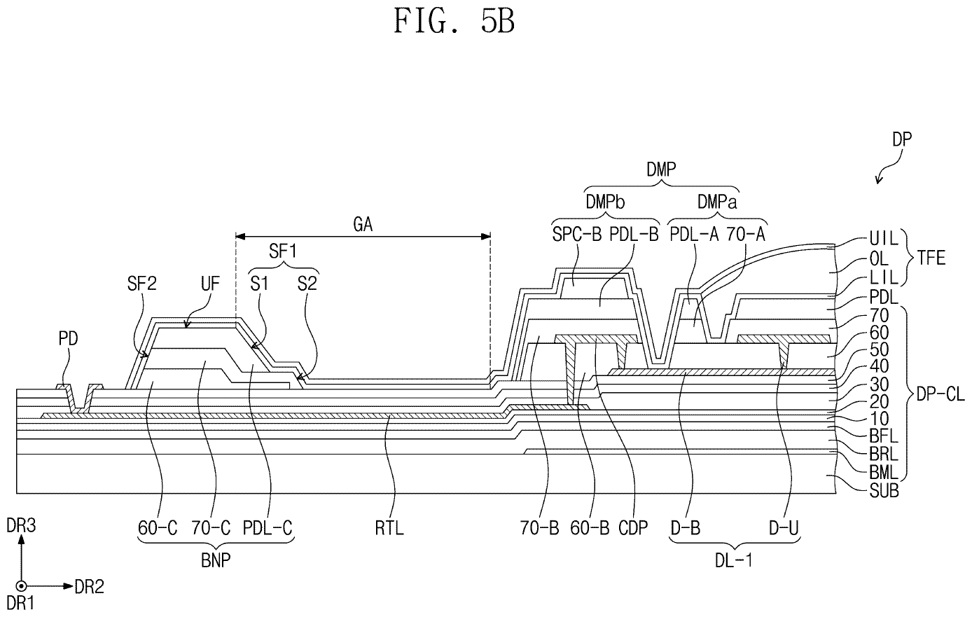

The pixel circuit PDC may include first to seventh transistors T1, T2, T3, T4, T5, T6, and T7, and first to third capacitors Cst, Cbst, and Nbst. According to the invention, the configuration of the pixel circuit PDC is not limited to the embodiment illustrated in FIG. 5. The pixel circuit PDC illustrated in FIG. 5A is only an example, and the configuration of the pixel circuit PDC may be changed and implemented.

At least one of the first to seventh transistors T1, T2, T3, T4, T5, T6, and T7 may be a transistor having a low-temperature polycrystalline silicon (LTPS) semiconductor layer. At least one of the first to seventh transistors T1, T2, T3, T4, T5, T6, and T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

Specifically, the first transistor T1, which directly affects brightness of the light-emitting element LD, includes a semiconductor layer containing polycrystalline silicon having high reliability. Resultantly, a high-resolution display device may be achieved. Meanwhile, since oxide semiconductor has high carrier mobility and low leakage current, voltage drop is not significant even when driving time is long. That is, low-frequency driving is possible since color change of an image due to the voltage drop is not significant even during low-frequency driving. Thus, since oxide semiconductor has an advantage of having low leakage current, at least one of the third transistor T3 and the fourth transistor T4 connected to a gate electrode of the first transistor T1 may be employed as oxide semiconductor, and thus leakage current which may flow to the gate electrode may be prevented and power consumption may be reduced as well.

The j-th initialization scan line GILj, the j-th compensation scan line GCLj, the j-th write scan line GWLj, the j-th black scan line GBLj, and the j-th emission control line ECLj may respectively transfer a j-th initialization scan signal GIj, a j-th compensation scan signal GCj, a j-th write scan signal GWj, a j-th black scan signal GBj, and a j-th emission control signal EMj to the pixel PXij. The i-th data line DLi transfers the i-th data signal Di to the pixel PXij. The i-th data signal Di may have a voltage level corresponding to an image signal input to the display device DD (see FIG. 3).

The first and second driving voltage lines VL1 and VL2 may respectively transfer a first driving voltage ELVDD and a second driving voltage ELVSS to the pixel PXij. In addition, the first and second initialization voltage lines VL3 and VL4 may respectively transfer a first initialization voltage VINT and a second initialization voltage VAINT to the pixel PXij.

The first transistor T1 is connected between the first driving voltage line VL1 for receiving the first driving voltage ELVDD and the light-emitting element LD. The first transistor T1 includes a first electrode connected to the first driving voltage line VL1 via the fifth transistor T5, a second electrode connected to a pixel electrode (or referred to as an anode) of the light-emitting element LD via the sixth transistor T6, and a third electrode (for example, a gate electrode) connected to one end (for example, a first node N1) of the first capacitor Cst. The first transistor T1 may receive the i-th data signal Di transferred by the i-th data line DLi according to a switching operation of the second transistor T2, and provide driving current to the light-emitting element LD.

The second transistor T2 is connected between the data line DLi and the first electrode of the first transistor T1. The second transistor T2 includes a first electrode connected to the data line DLi, a second electrode connected to the first electrode of the first transistor T1, and a third electrode (for example, a gate electrode) connected to the j-th write scan line GWLj. The second transistor T2 may be turned on in response to the write scan signal GWj which is received through the j-th write scan line GWLj, and transfer the i-th data signal Di transferred from the i-th data line DLi to the first electrode of the first transistor T1. One end of the second capacitor Cbst may be connected to the third electrode of the second transistor T2, and the other end of the second capacitor Cbst may be connected to the first node N1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (for example, a gate electrode) connected to the j-th compensation scan line GCLj. The third transistor T3 may be turned on in response to the j-th compensation scan signal GCj which is received through the j-th compensation scan line GCLj to connect the third electrode of the first transistor T1 and the second electrode of the first transistor T1 to each other, so that the first transistor T1 may be diode-connected. One end of the third capacitor Nbst may be connected to the third electrode of the third transistor T3, and the other end of the third capacitor Nbst may be connected to the first node N1.

The fourth transistor T4 is connected between the first node N1 and the first initialization voltage line VL3 to which the first initialization voltage VINT is applied. The fourth transistor T4 includes a first electrode connected to the first initialization voltage line VL3 to which the first initialization voltage VINT is transferred, a second electrode connected to the first node N1, and a third electrode (for example, a gate electrode) connected to the j-th initialization scan line GILj. The fourth transistor T4 is turned on in response to the j-th initialization scan signal GIj which is received through the j-th initialization scan line GILj. The turned-on fourth transistor T4 transfers the first initialization voltage VINT to the first node N1 and initializes electric potential of the third electrode of the first transistor T1 (that is, electric potential of the first node N1).

The fifth transistor T5 includes a first electrode connected to the first driving voltage line VL1, a second electrode connected to the first electrode of the first transistor T1, and a third electrode (for example, a gate electrode) connected to the j-th emission control line ECLj. The sixth transistor T6 includes a first electrode connected to the second electrode of the first transistor T1, a second electrode connected to the pixel electrode of the light-emitting element LD (for example, relative to a second node N2), and a third electrode (for example, a gate electrode) connected to the j-th emission control line ECLj.

The fifth and sixth transistors T5 and T6 are simultaneously turned on in response to the j-th emission control signal EMj which is received through the j-th emission control line ECLj. The first driving voltage ELVDD applied via the turned-on fifth transistor T5 may be compensated by the diode-connected first transistor T1, and then transferred to the light-emitting element LD via the sixth transistor T6.

The seventh transistor T7 includes a first electrode connected to the second initialization voltage line VL4 to which the second initialization voltage VAINT is transferred, a second electrode connected to the second electrode of the sixth transistor T6, and a third electrode (for example, a gate electrode) connected to the black scan line GBLj. The second initialization voltage VAINT may have a voltage level which is lower than or the same as that of the first initialization voltage VINT.

One end of the first capacitor Cst is connected to the third electrode of the first transistor T1, and the other end of the first capacitor Cst is connected to the first driving voltage line VL1. A cathode of the light-emitting element LD may be connected to the second driving voltage line VL2 for transferring the second driving voltage ELVSS. The second driving voltage ELVSS may have a voltage level which is lower than that of the first driving voltage ELVDD.

Some of the first to seventh transistors T1, T2, T3, T4, T5, T6, and T7 may be P-type transistors, and the rest may be N-type transistors. For example, the first, second, fifth, sixth, and seventh transistors T1, T2, T5, T6, and T7 may be P-type transistors, and the third and fourth transistors T3 and T4 may be N-type transistors.

Meanwhile, the configuration of the pixel circuit PDC according to the invention is not limited to the embodiment illustrated in FIG. 4B. The pixel circuit PDC illustrated in FIG. 4B is only an example, and the configuration of the pixel circuit PDC may be changed and implemented. For example, the first to seventh transistors T1, T2, T3, T4, T5, T6, and T7 may be P-type transistors, or all may be N-type transistors. Alternatively, the first, second, fifth, and sixth transistors T1, T2, T5, and T6 may be P-type transistors, and the third, fourth, and seventh transistors T3, T4, and T7 may be N-type transistors. In addition, the number of transistors or the number of capacitors constituting the pixel circuit PDC according to an embodiment of the invention may be changed in various ways and is not limited to any one embodiment.

Referring back to FIG. 4A, the first control line CSL1 may be connected to the scan driving part SDV and extend toward a lower end of the non-display region DP-NDA. The second control line CSL2 may be connected to the emission driving part EDV and extend toward the lower end of the non-display region DP-NDA.

In a plan view, the pads PD (or pad part PD) may be disposed adjacent to the lower end of the non-display region DP-NDA. In this embodiment, the pads PD may be disposed spaced apart from each other along the first direction DR1. The pads PD may be defined on ends extending to the lower end of the non-display region DP-NDA among ends of signal lines extending along the second direction DR2. In this embodiment, the pads PD may be defined on ends of the first control line CSL1, the second control line CSL2, and the driving voltage line PL, and ends of lines connected to the driving chip DIC. Meanwhile, pads overlapping the driving chip DIC and connected to the driving chip DIC may be defined on ends of the data lines DL1 to DLn, and the data lines DL1 to DLn may be electrically connected to the pads PD. A circuit board FCB may be electrically connected to the pads PD via an anisotropic conductive adhesive layer.

Meanwhile, the display panel DP according to an embodiment of the invention may include a dam part DMP and a bank BNP. The dam part DMP as a dam may extend along a border of the display region DP-DA. The dam part DMP may have a frame shape which surrounds the display region DP-DA. The dam part DMP may include at least one organic film. The dam part DMP may otherwise be considered a “bank” of the display panel DP.

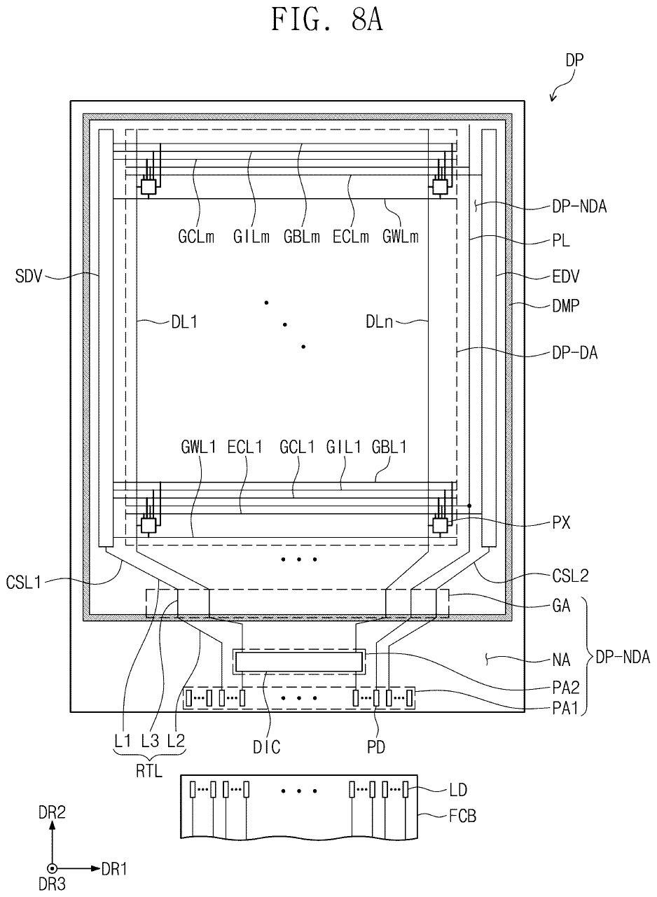

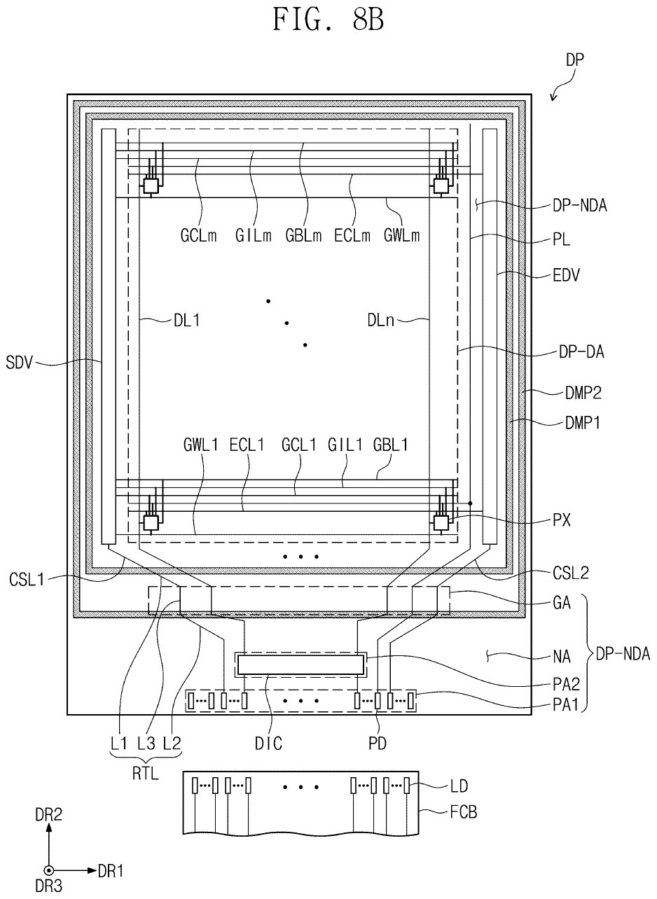

The bank BNP is disposed spaced apart from the dam part DMP. The bank BNP may be disposed between the display region DP-DA and a pad region PA. The pad region may be provided in plural include a first pad region PA1 and a second pad region PA2 (refer to FIGS. 8A and 8B). The first pad region PA1 may be a region in which pads PD as first pads, on which the circuit board FCB is disposed, are disposed. The second pad region PA2 may be a region in which second pads (not illustrated) for being connected to the driving chip DIC are disposed, and may overlap the driving chip DIC. Meanwhile, this is illustrated as an example, and any one of the first pad region PA1 and the second pad region PA2 may be omitted so that only one region thereof may be present, but an embodiment of the invention is not limited to any one embodiment.

The bank BNP may have a bar shape having a major dimension extending along the first direction DR1. The bank BNP may extend across fan-out lines RTL. The bank BNP may overlap the fan-out lines RTL in a plan view. The bank BNP may include at least one organic film.

In this embodiment, the non-display region DP-NDA may include a normal region NA and a stepped region GA. The normal region NA may be a region other than the stepped region GA, such as a region surrounding the stepped region GA. The normal region NA, the stepped region GA and the pad region PA may be disposed at a lower portion of the non-display region DP-NDA.

The stepped region GA may be present between the driving chip DIC and the active region AA (or the display region DP-DA) or between the pads PD and the active region AA. The stepped region GA may overlap at least a portion of the bank BNP in a plan view. A side surface of the bank BNP, overlapping the stepped region GA may include two or more sections with different angles of inclination. The angle of inclination may be less than about 90 degrees. According to the invention, the side surface of the bank BNP may be segmented into sections having relatively small angles of inclination in the stepped region GA, and thus a step of the side surface of the bank BNP may be formed in a shape having relatively slow and continuous curves. Accordingly, an inorganic layer, which covers the side surface of the bank BNP, may be prevented from not being deposited or from being damaged due to pressure. This will be described in detail later.

In addition, the stepped region GA may overlap at least a portion of the fan-out lines RTL in a plan view. The fan-out lines RTL may be an extended portion of the signal lines in the display region DP-DA, or may be a conductive line separated from the signal lines and formed in the non-display region DP-NDA. The fan-out line RTL may extend to a pad region PA along the second direction DR2. One end of the fan-out line RTL may be connected to the driving chip DIC or may be provided to the pad PD to be connected to the circuit board FCB.

The fan-out line RTL may be divided into a first part L1, a second part L2, and a third part L3 along the length of a respective fan-out line. The first part L1 may be disposed between the active region AA (or the display region DP-DA), and the third part L3 may be inclined with respect to the second direction DR2.

Portions, of the signal lines, overlapping the stepped region GA may be parallel to the second direction DR2 in a plan view. That is, the portions, of the signal lines, overlapping the stepped region GA may not include (e.g., may exclude) an inclined part crossing the second direction DR2. Accordingly, an area of the signal line crossing the stepped region GA may be minimized, and thus a possibility of the signal line being damaged in the stepped region GA may be reduced. As being overlapping, elements may be disposed along a same line in a direction, such as along a thickness direction, a lateral direction, etc. For example, one element may be above or below another element along a thickness direction, so as to be be considered overlapping each other, without being limited thereto. This will be described in detail later.

The stepped region GA may overlap at least a portion of an organic film more adjacent to the lower end of the non-display region DP-NDA among organic films disposed between the pads PD and the active region AA (or the display region DP-DA). In this embodiment, since the bank BNP is relatively closer to the pads PD or the driving chip DIC than the dam part DMP, the stepped region GA may be defined overlapping at least a portion of the bank BNP. However, this is illustrated as an example, and the stepped region GA may overlap the dam part DMP or another organic film if the bank BNP is relatively closer to the pads PD or the driving chip DIC than the dam part DMP, and is not limited to any one embodiment.

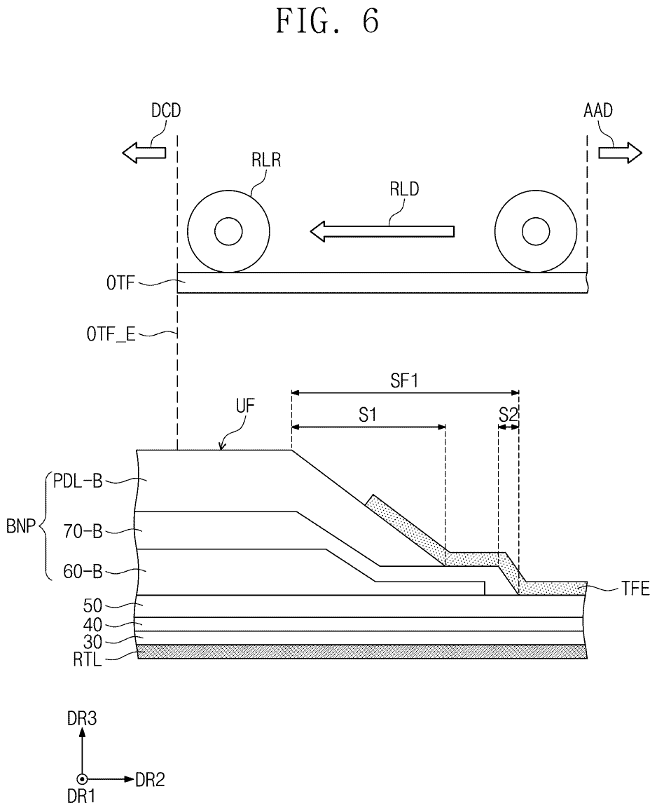

FIGS. 5A and 5B are each an enlarged cross-sectional view of one region of a display panel DP according to an embodiment of the invention. FIG. 6 is a schematic view of a process in a method of manufacturing (or providing) a display panel DP according to an embodiment of the invention.

FIG. 5A illustrates a region in which a portion of a pixel PX is disposed, and FIG. 5B illustrates a region in which a stepped region GA is disposed. FIG. 6 illustrates an enlarged view of some components illustrated in FIG. 5B, that is, at an end portion of the display panel DP. Hereinafter, the invention will be described with reference to FIGS. 5A to 6. Meanwhile, components which are the same as the components described with reference to FIGS. 1 to 4B will be denoted as the same reference numerals or symbols, and duplicated descriptions will be omitted.

FIG. 5A illustrates two transistors TR1 and TR2, hereinafter a first transistor TR1 and a second transistor TR2, and the light-emitting element OLED (for example, LD in FIG. 4B). Each of the first transistor TR1 and the second transistor TR2 is corresponding to one of transistors of the pixel PXij illustrated in FIG. 4B. FIG. 5A illustrates the base layer SUB, the circuit element layer DP-CL, the display element layer DP-OLED and the encapsulation layer TFE illustrated in FIG. 3B in more detail.

The base layer SUB may include a plurality of layers stacked along the third direction DR3. In this embodiment, the base layer SUB may include a first base layer PI1, a first cover layer BR1, a second base layer PI2 and a second cover layer BR2. However, this is illustrated as an example, and the base layer SUB may be a single layer or may include other number of layers and is not limited to any one embodiment.

The first base layer PI1 may be disposed on a lowermost side. The first base layer PI1 may include an organic material. For example, the first base layer PI1 may include one of polyimide (PI), polyethylene naphthalate (PEN), polyethylene terephthalate (PET), polyarylate, polycarbonate (PC), polyetherimide (PEI) and polyethersulfone (PES).

The first cover layer BR1 may be disposed on the first base layer PI1. The first cover layer BR1 may include an inorganic material. For example, the first cover layer BR1 may include at least one of silicon oxide, silicon oxynitride, aluminum oxide, titanium oxide, silicon nitride, zirconium oxide, hafnium oxide and amorphous silicon.

The second base layer PI2 may be disposed on the first cover layer BR1. The second base layer PI2 may include an organic material. The organic material included in the second base layer PI2 may be the same as the organic material included in the first base layer PI1.

The second cover layer BR2 may be disposed on the second base layer PI2. The second cover layer BR2 may include an inorganic material. The inorganic material included in the second cover layer BR2 may be the same as the inorganic material included in the first cover layer BR1.

The circuit element layer DP-CL may be disposed on the second cover layer BR2. The circuit element layer DP-CL includes at least a plurality of insulating layers and a circuit element. Hereinafter, the insulating layers may include an organic layer and/or an inorganic layer. The circuit element includes a signal line, a driving circuit of a pixel PX, etc. The circuit element layer DP-CL may be formed through a process of forming an insulating layer, a semiconductor layer and a conductive layer by coating, deposition, or the like and a process of patterning the insulating layer, the semiconductor layer and the conductive layer by a photolithography process.

In this embodiment, a light shielding pattern BML may be disposed at a lowermost portion of the circuit element layer DP-CL. That is, the light shielding pattern BML may be disposed on the second cover layer BR2. The light shielding pattern BML as a light-blocking layer (or electrical-shielding layer) may block electric potential caused by a polarization phenomenon from affecting the first transistor T1. In addition, the light shielding pattern BML may block external light from reaching the first transistor T1. In an embodiment of the invention, the light shielding pattern BML may be a floating electrode (or floating conductive pattern) which is isolated from another electrode or electrically conductive line. The light shielding pattern BML may include molybdenum.

A barrier layer BRL may be disposed on the light shielding pattern BML. The barrier layer BRL prevents foreign substances from being introduced from the outside. The barrier layer BRL may include a silicon oxide layer and a silicon nitride layer. Each of the silicon oxide layer and the silicon nitride layer may be provided in plurality, and the silicon oxide layers and the silicon nitride layers may be alternately stacked.

A buffer layer BFL may be disposed on the barrier layer BRL. The buffer layer BFL improves a bonding force between a base layer SUB and conductive patterns or semiconductor patterns. The buffer layer BFL may include a silicon oxide layer and a silicon nitride layer. The silicon oxide layer and the silicon nitride layer may be alternately stacked.

A first semiconductor pattern SP1 is disposed on the buffer layer BFL. The first semiconductor pattern SP1 may include silicon semiconductor. The first semiconductor pattern SP1 may be polysilicon semiconductor. However, an embodiment of the invention is not limited thereto, and the first semiconductor pattern SP1 may include amorphous silicon.

The first semiconductor pattern SP1 may include an input region (or a first part), an output region (or a second part) and a channel region (or a third part) defined between the input region and the output region. The channel region of the first semiconductor pattern SP1 may be defined corresponding to a first control electrode GE1 to be described later. The input region and the output region are doped with a dopant and have relatively high conductivity compared to the channel region. The input region and the output region may be doped with an n-type dopant. In this embodiment, the n-type first transistor T1 is described as an example, but the first transistor T1 may be a p-type transistor.

A first insulating layer 10 is disposed on the buffer layer BFL. The first insulating layer 10 overlaps the plurality of pixels PX (see FIG. 2) in common and covers the first semiconductor pattern SP1. The first insulating layer 10 may be an inorganic layer and/or an organic layer and have a single-layered or multilayer structure. The first insulating layer 10 may include at least one of aluminum oxide, titanium oxide, silicon oxide, silicon oxynitride, zirconium oxide, and hafnium oxide. In this embodiment, the first insulating layer 10 may be a single-layered silicon oxide layer.

The first control electrode GE1 is disposed on the first insulating layer 10. The first control electrode GE1 overlaps the channel region of the first semiconductor pattern SP1.

A second insulating layer 20 covering the first control electrode GE1 is disposed on the first insulating layer 10. The second insulating layer 20 overlaps the plurality of pixels PX (see FIG. 1) in common. The second insulating layer 20 may be an inorganic layer and/or an organic layer and have a single-layered or multilayer structure. The second insulating layer 20 may include at least one of aluminum oxide, titanium oxide, silicon oxide, silicon oxynitride, zirconium oxide and hafnium oxide. In this embodiment, the second insulating layer 20 may be a single-layered silicon oxide layer.

An upper electrode UE may be further disposed on the second insulating layer 20. The upper electrode UE may overlap the first control electrode GE1.

A lower control electrode GE2-B of the second transistor T2 may be further disposed on the second insulating layer 20. The lower control electrode GE2-B may overlap a second semiconductor pattern SP2. The lower control electrode GE2-B and an upper control electrode GE2-U together may form a dual gate.

The lower control electrode GE2-B and the upper electrode UE may be in a same layer as each other.

As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

A third insulating layer 30 covering the upper electrode UE and the lower control electrode GE2-B, is disposed on the second insulating layer 20. The third insulating layer 30 may be an inorganic layer and/or an organic layer and have a single-layered or multilayer structure. The third insulating layer 30 may include at least one of aluminum oxide, titanium oxide, silicon oxide, silicon oxynitride, zirconium oxide and hafnium oxide. In this embodiment, the third insulating layer 30 may be a single-layered silicon oxide layer.

The second semiconductor pattern SP2 is disposed on the third insulating layer 30. The second semiconductor pattern SP2 may include oxide semiconductor. The second semiconductor pattern SP2 may include crystalline or amorphous oxide semiconductor. For example, the oxide semiconductor may include metal oxide of zinc (Zn), indium (In), gallium (Ga), tin (Sn), titanium (Ti), and the like or a mixture of metal such as zinc (Zn), indium (In), gallium (Ga), tin (Sn) and titanium (Ti) and oxide thereof. The oxide semiconductor may include indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), zinc-tin oxide (ZTO), etc.

The second semiconductor pattern SP2 may include an input region (or a first part), an output region (or a second part) and a channel region (or a third part) defined between the input region and the output region. The input region and the output region may include impurities. The channel region of the second semiconductor pattern SP2 may be defined corresponding to an upper control electrode GE2-U to be described later.

The impurities of the second semiconductor pattern SP2 may be reduced metal materials. The input region and the output region may include metal materials which are reduced from metal oxide included in the channel region. Accordingly, the seventh transistor T7 may reduce leakage current and thus function as a switching element with improved on-off characteristics.

A fourth insulating layer 40 covering the second semiconductor pattern SP2 is disposed on the third insulating layer 30. The fourth insulating layer 40 may be an inorganic layer and/or an organic layer and have a single-layered or multilayer structure. The fourth insulating layer 40 may include at least one of aluminum oxide, titanium oxide, silicon oxide, silicon oxynitride, zirconium oxide and hafnium oxide.

The upper control electrode GE2-U is disposed on the fourth insulating layer 40. The upper control electrode GE2-U overlaps the second semiconductor pattern SP2.

A fifth insulating layer 50 covering the upper control electrode GE2-U is disposed on the fourth insulating layer 40. The fifth insulating layer 50 may be an inorganic layer and/or an organic layer and have a single-layered or multilayer structure. The fifth insulating layer 50 may include at least one of aluminum oxide, titanium oxide, silicon oxide, silicon oxynitride, zirconium oxide and hafnium oxide.

A first input electrode DE1, a first output electrode SE1, a second input electrode DE2 and a second output electrode SE2 are disposed on the fifth insulating layer 50. The first input electrode DE1 and the first output electrode SE1 are connected to the first semiconductor pattern SP1 through a first contact hole CH1 and a second contact hole CH2 exposing the input region and the output region of the first semiconductor pattern SP1, respectively. The first contact hole CH1 and the second contact hole CH2 penetrate the first insulating layer 10 to the fifth insulating layer 50. One or more insulating layer among the first insulating layer 10 to the fifth insulating layer 50 may be otherwise referred to as “an insulating layer.”

The second input electrode DE2 and the second output electrode SE2 are connected to the second semiconductor pattern SP2 through a third contact hole CH3 and a fourth contact hole CH4 exposing the input region and the output region of the second semiconductor pattern SP2, respectively. The third contact hole CH3 and the fourth contact hole CH4 penetrate the fifth insulating layer 50.

A display panel DP according to an embodiment may further include a control bridge pattern BBP disposed on the fourth insulating layer 40. The control bridge pattern BBP may be branched off from a portion of the upper control electrode GE2-U. That is, the control bridge pattern BBP and the upper control electrode GE2-U may be a unitary body, in a same layer as each other, etc. The control bridge pattern BBP may be connected to the lower control electrode GE2-B through a fifth contact hole CH5. The fifth contact hole CH5 penetrates the third insulating layer 30 and the fourth insulating layer 40.

A sixth insulating layer 60 covering the first input electrode DE1, the first output electrode SE1, the second input electrode DE2 and the second output electrode SE2 is disposed on the fifth insulating layer 50. The sixth insulating layer 60 may be an organic layer and have a single-layered or multilayer structure.

A connection electrode CNE is disposed on the sixth insulating layer 60. The connection electrode CNE may be connected to the second output electrode SE2 through a sixth contact hole CH6 penetrating the sixth insulating layer 60.

A seventh insulating layer 70 (or a passivation layer) covering the connection electrode CNE is disposed on the sixth insulating layer 60. The seventh insulating layer 70 may be an organic layer and have a single-layered or multilayer structure.

In this embodiment, the sixth insulating layer 60 and the seventh insulating layer 70 may be a single-layered polyimide-based resin layer. An embodiment of the invention is not limited thereto, and the sixth insulating layer 60 and the seventh insulating layer 70 may include at least one of an acrylic resin, a methacrylic resin, polyisoprene, a vinyl-based resin, an epoxy-based resin, a urethane-based resin, a cellulose-based resin, a siloxane-based resin, a polyamide-based resin and a perylene-based resin.

A light-emitting element OLED is disposed on the seventh insulating layer 70. An anode AE of the light-emitting element OLED is disposed on the seventh insulating layer 70. The anode AE is connected to the connection electrode CNE through a seventh contact hole CH7 penetrating the seventh insulating layer 70.

The display element layer DP-OLED may include the light-emitting element OLED and a pixel-defining film PDL. The pixel-defining film PDL is disposed on the seventh insulating layer 70. At least one opening OP may be defined in the pixel-defining film PDL. The opening OP of the pixel-defining film PDL exposes at least a portion of the anode AE to outside the pixel-defining film PDL. The opening OP of the pixel-defining film PDL may define a light-emitting region PXA of a pixel PX. For example, the plurality of pixels PX (see FIG. 4A) may be arranged according to a certain rule in a plan view of the display panel DP. A region in which the plurality of pixels PX are arranged may correspond to the display region DP-DA described with reference to FIG. 4A, and the display region DP-DA may include light-emitting regions PXA and a non-light-emitting region NPXA which is adjacent to the light-emitting regions PXA. The non-light-emitting region NPXA may surround the light-emitting regions PXA in the plan view.

A hole control layer HCL may be disposed in the light-emitting regions PXA and the non-light-emitting region NPXA in common. A common layer such as the hole control layer HCL may be formed in the plurality of pixels PX (see FIGS. 4A and 5A) in common. The hole control layer HCL may include a hole transport layer and a hole injection layer.

An organic light-emitting layer EML is disposed on the hole control layer HCL. The organic light-emitting layer EML may be disposed only in a region corresponding to the opening OP. The organic light-emitting layer EML may be separately formed in each of the plurality of pixels PX (see FIG. 2).

In this embodiment, the patterned organic light-emitting layer EML is illustrated as an example, but the organic light-emitting layer EML may be disposed in the plurality of pixels PX in common. In this case, the organic light-emitting layer EML may generate white light. In addition, the organic light-emitting layer EML may have a multilayer structure.

An electron control layer ECL is disposed on the organic light-emitting layer EML. The electron control layer ECL may include an electron transport layer and an electron injection layer. A cathode CE is disposed on the electron control layer ECL. The electron control layer ECL and the cathode CE are disposed in the plurality of pixels PX (see FIG. 2) in common.

The encapsulation layer TFE is disposed on the cathode CE. The encapsulation layer TFE is disposed in the plurality of pixels PX in common. In this embodiment, the encapsulation layer TFE directly covers the cathode CE. The encapsulation layer TFE may cover the light-emitting element OLED. The encapsulation layer TFE may include two inorganic encapsulation layers LIL and UIL and an organic encapsulation layer OL disposed therebetween. In an embodiment of the invention, the encapsulation layer TFE may include a plurality of inorganic layers and a plurality of organic layers which are alternately stacked.

The inorganic encapsulation layers LIL and UIL protect the light-emitting element OLED from moisture/oxygen, and the organic encapsulation layer OL protects the light-emitting element OLED from foreign substances such as dust particles. The inorganic encapsulation layers LIL and UIL may include a silicon nitride layer, a silicon oxynitride layer, a silicon oxide layer, a titanium oxide layer, an aluminum oxide layer, or the like and are not particularly limited thereto. The organic encapsulation layer OL may include an acrylic organic layer and is not particularly limited.

One more layer among layers PI1 through UIL may extend from the display region DP-DA to the non-display region DP-NDA.

Referring to FIG. 5B, a dam part DMP may be formed by stacking patterns in same layers as at least some of insulating layers constituting a display panel DP. In this embodiment, the dam part DMP may include a first dam part DMPa and a second dam part DMPb. The first dam part DMPa as a first dam and the second dam part DMPb as a second dam may be patterns of various layers of the display area DP-DA which are partially separated through a predetermined opening. The first dam part DMPa may be disposed on a sixth insulating layer 60 and have a structure in which a second layer 70-A which is in the same layer as a seventh insulating layer 70, and a third layer PDL-A which is in the same layer as a pixel-defining film PDL, are stacked. The second dam part DMPb may include a first layer 60-B which is in the same layer as the sixth insulating layer 60, a second layer 70-B which is in the same layer as the seventh insulating layer 70, a third layer PDL-B which is in the same layer as the pixel-defining film PDL, and a fourth layer SPC-B, are stacked. The fourth layer SPC-B may be additionally stacked on the third layer PDL-B and include an organic material. The dam part DMP may include organic layers. Thus, the dam part DMP may be formed to have a predetermined height and may prevent overflow of material, such as during forming an organic layer OL of an encapsulation layer TFE.

Meanwhile, a conductive pattern CDP may be disposed between adjacent layers constituting the dam part DMP. The conductive pattern CDP may electrically connect a fan-out line RTL and a data line DL-1 to each other. In this embodiment, the data line DL-1 may include a first layer D-B as a lower layer and a second layer D-U as an upper layer. However, this is illustrated as an example, and the data line DL-1 may be a single layer, or the conductive pattern CDP may be omitted. In this case, the data line DL-1 may partially extend to define an extended portion of the data line DL-1 which constitutes the fan-out line RTL, and is not limited to any one embodiment. In addition, the number of layers constituting the dam part DMP may not be limited, and the dam part DMP may be formed as a single organic layer.

A bank BNP is disposed spaced apart from the dam part DMP at the end portion of the display panel DP. The bank BNP may be disposed between a plurality of pads PD and the display region DP-DA. The pad PD may be connected to the fan-out line RTL. The pad PD may be a connection part connected to the driving chip DIC described above or the pad PD connected to the circuit board FCB and is not limited to any one embodiment.

The bank BNP may be formed by stacking at least some of the insulating layers constituting the display panel DP. In this embodiment, the bank BNP may include a first layer 60-C which is in the same layer as the sixth insulating layer 60, a second layer 70-C which is in the same layer as the seventh insulating layer 70, and a third layer PDL-C which is in the same layer as the pixel-defining film PDL. The bank BNP may include a first side surface SF1 facing or closest to the display region DP-DA and a second side surface SF2 facing the pad PD. The second side surface SF2 may be oriented in an opposite direction to the first side surface SF1 in the second direction DR2.

The first side surface SF1 may include two or more inclined parts S1 and S2. The inclined parts S1 and S2 may have different angles of inclination from each other. The angle of inclination may be an angle of inclination with respect to an upper surface of a base layer SUB and may be less than about 90 degrees. The inclined parts S1 and S2 may include a first inclined part S1 and a second inclined part S2. The first inclined part S1 may be a surface connected to an upper surface UF of the bank BNP, and the second inclined part S2 may be disposed lower than the first inclined part S1, that is, closer to the base layer SUB. In this embodiment, it is illustrated that a flat surface is between the first inclined part S1 and the second inclined part S2, but an embodiment of the invention is not limited thereto. An additional inclined part may be further included at the upper surface UF between the first inclined part S1 and the second inclined part S2, and an embodiment of the invention is not limited to any one embodiment.

In this embodiment, the first inclined part S1 and the second inclined part S2 may be defined by different layers from each other. For example, the first inclined part S1 may be defined by a side surface of the third layer PDL-C, and the second inclined part S2 may be defined by a side surface of the second layer 70-C. However, this is illustrated as an example, and the first inclined part S1 and the second inclined part S2 may be defined by one layer and are not limited to any one embodiment.

The second side surface SF2 may have various shapes in cross-section. In this embodiment, the second side surface SF2 is illustrated as an inclined part having a single angle of inclination different from that of the first side surface SF1. The side surfaces may not be aligned with each other, that is, may be in different DR1-DR3 planes. However, this is illustrated as an example, and the second side surface SF2 may have the same shape as the first side surface SF1 such as to be coplanar with each other, have an inclined surface in a different shape, or may not have an inclined part, and is not limited to any one embodiment.

According to the invention, the bank BNP may be an organic film structure which is most adjacent to the pad PD, and step change in the first side surface SF1 may be reduced by forming the first side surface SF1 as a plurality of inclined parts.

Specifically, referring to FIG. 6, attaching an optical film OTF to a portion of a display panel DP is illustrated. An end portion of an encapsulation layer TFE, in contact with a bank BNP is schematically illustrated as a single inorganic layer for convenience of illustration.

Attaching the optical film OTF may include providing a force along the optical film OTF, by using a roller RLR. The roller RLR may roll along a rolling direction RLD and press the optical film OTF towards layers of the display panel DP, and the optical film OTF may be attached to an upper surface of the display panel DP via an adhesive layer (not illustrated).

The rolling direction RLD may be a direction from a center of the display region DP-DA to the pads PD, that is, from the display region DP-DA to the pad region PA. In FIG. 6, a direction AAD toward the display region DP-DA from the pad region PA, and a direction DCD to the pads PD from the display region DP-DA are respectively indicated by arrows.

As described above, a first side surface SF1 of the bank BNP may include two or more inclined parts S1 and S2 having different angles of inclination from each other. A first inclined part S1 and a second inclined part S2 have different angles of inclination from each other. In addition, in this embodiment, the first inclined part S1 and the second inclined part S2 may be respectively defined by upper surfaces of different organic layers but are not limited thereto.

The encapsulation layer TFE is in contact with a fifth insulating layer 50 which is an inorganic layer, extends along the first side surface SF1 of the bank BNP and covers at least a portion of the first side surface SF1. The fifth insulating layer 50 which is an inorganic layer may form a step together with the inclined parts S1 and S2 of the first side surface SF1 of the bank BNP.

As the optical film OTF is rolled, pressure applied from the roller RLR may be transferred to the bank BNP due to a protruding shape of the bank BNP. In this case, the first side surface SF1 of the bank BNP may be a surface facing the roller RLR and first contacted by the roller RLR in the rolling direction RLD. As a height within the step of the first side surface SF1 is large, and as a height of an upper surface UF of the bank BNP is great, an impact according to collision with the roller RLR may be significant. However, even if a total degree of protrusion of the bank BNP is great, repulsion of the bank BNP against moving of the roller RLR may be minimized when a total distance of the step of the first side surface SF1 along the second direction DR2 is gradually segmented into two different inclines. That is, an effect of the bank BNP during moving of the roller RLR may be reduced, and thus the roller RLR may smoothly roll up to the upper surface UF of the bank BNP and press the optical film OTF.

A first step may be defined by the incline of the second inclined part S2 together with a portion of the bank BNP between the second inclined part S2 and the first inclined part S1. Here, the portion may have an inclination angle less than that of the second inclined part S2, such as being flat.

Thus, according to the invention, an impact according to collision between the optical film OTF and the bank BNP during a process of attaching the optical film OTF may be minimized by segmenting inclined parts so that the first side surface SF1 of the bank BNP has a plurality of angles of inclination and minimizing a height of a step of the first side surface SF1 of the bank BNP, and damage to the lower inorganic layers 10, 20, 30, 40 and 50 due to the impact may be minimized. Accordingly, risk of occurrence of a defect in which the fan-out line RTL is damaged by infiltration of moisture due to damage to the lower inorganic layers 10, 20, 30, 40 and 50 may be reduced, and manufacturing process reliability of an electronic apparatus may be improved.

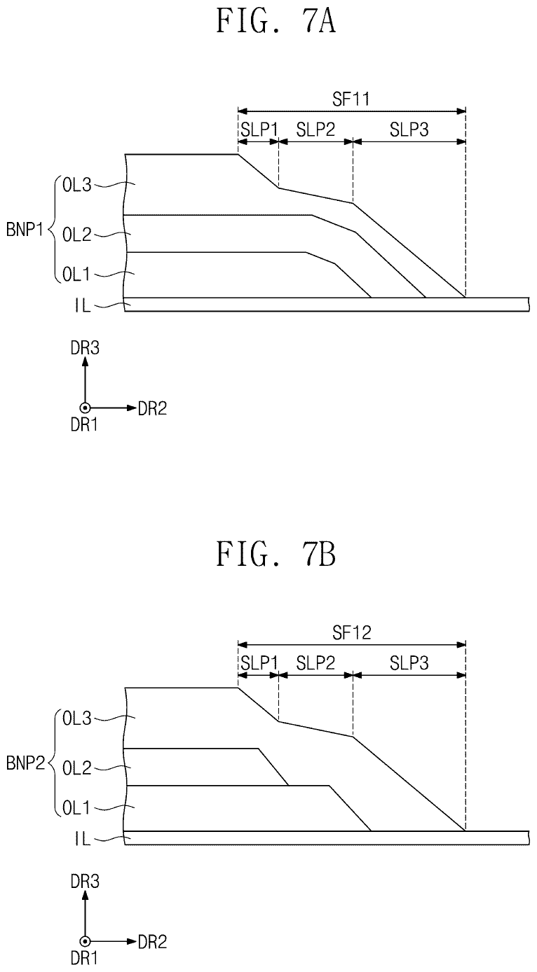

FIGS. 7A and 7B are each a schematic cross-sectional view of a bank BNP according to an embodiment of the invention. Hereinafter, the invention will be described with reference to FIGS. 7A and 7B. Meanwhile, components which are the same as the components described with reference to FIGS. 1 to 6 will be denoted as the same reference numerals or symbols, and duplicated descriptions will be omitted.

Referring to FIGS. 7A and 7B, banks BNP1 and BNP2 may be each formed by stacking three organic layers OL1, OL2 and OL3, on an inorganic layer IL. The inorganic layer IL may be a layer covering the fan-out line RTL (see FIG. 4A) and include at least one of the insulating layers 10, 20, 30, 40 and 50 illustrated in FIG. 5B. Each of the organic layers OL1, OL2 and OL3 may be one of the organic layers 60, 70 and PDL illustrated in FIG. 5B or an additionally provided organic layer and is not limited to any one embodiment.

Referring to FIG. 7A, a first side surface SF11 of the bank BNP1 may include plurality of inclined parts SLP1, SLP2 and SLP3. The inclined parts SLP1, SLP2 and SLP3 may include first to third inclined parts SLP1, SLP2 and SLP3 each having a predetermined angle of inclination with respect to the second direction DR2, and at least two inclined parts may have different angles of inclination from each other. In this embodiment, an angle of inclination of the first side surface SF11 may decrease in the second inclined part SLP2 compared to the first inclined part SLP1 and increase in the third inclined part SLP3 relative to the second inclined part SLP2. That is, an inclination angle of the first side surface SF11 may both decrease and increase along the second direction DR2 It is illustrated that an angle of inclination of the third inclined part SLP3 is greater than an angle of inclination of the first inclined part SLP1, but an embodiment of the invention is not limited thereto, and an angle of inclination of the third inclined part SLP3 may be smaller than or the same as an angle of inclination of the first inclined part SLP1.

A second organic layer OL2 covers both an upper surface and a side surface of a first organic layer OL1, and a third organic layer OL3 covers both an upper surface and a side surface of the second organic layer OL2. The first side surface SF11 of the bank BNP1 may be defined by a side surface of the third organic layer OL3. In this case, the third organic layer OL3 may have an upper surface at a higher position than the upper surface of the second organic layer OL2 and include inclined parts which are further segmented than the side surface of the second organic layer OL2. According to the invention, inclinations of a step according to a height of the bank BNP1 may be gradually segmented by forming the plurality of inclined parts SLP1, SLP2 and SLP3 along the first side surface SF11. Accordingly, step change in the first side surface SF11 may be reduced, and thus an impact according to collision of a roller RLR with the bank BNP1 at the third inclined part SLP3 during a process of attaching the optical film OTF (see FIG. 6) may be minimized.

Referring to FIG. 7B, a first side surface SF12 of the bank BNP2 may include plurality of inclined parts SLP1, SLP2 and SLP3. The first side surface SF12 of the bank BNP2 may have a shape corresponding to the bank BNP1 described above, and thus duplicated descriptions will be omitted.

The first side surface SF12 of the bank BNP2 may be defined by a side surface of a third organic layer OL3. However, a stacking form of the organic layers OL1, OL2 and OL3 may be different from that of FIG. 7A. Specifically, a second organic layer OL2 may cover only an upper surface of a first organic layer OL1 and expose a side surface of the first organic layer OL1. The third organic layer OL3 may cover not only an upper surface and a side surface of the second organic layer OL2 but also the exposed side surface of the first organic layer OL1.

In an embodiment, the first side surface SF12 of the bank BNP2 may be controlled according to a stacking form and an angle of the first organic layer OL1 and the second organic layer OL2. According to the invention, a step according to a height of the bank BNP2 may be gradually segmented by forming a plurality of inclined parts SLP1, SLP2 and SLP3 at the first side surface SF12. Accordingly, step change in the first side surface SF12 may be reduced, and thus an impact according to collision of a roller RLR with the bank BNP2 at the third inclined part SLP3 during a process of attaching the optical film OTF (see FIG. 6) may be minimized.

Referring to FIGS. 6, 7A and 7B, for each portion of the side surface defined by a change in inclination angle, like SLP3 (at a first angle), SLP2 (at a second angle) and SLP1 in order, the second angle following the first angle along the rolling direction RLD may be smaller than the first angle. The stepped region GA may be defined from the end of the first side surface SF1 toward the dam part DMP. Referring to FIGS. 4A and 5B, for example, the stepped region GA may not overlap the dam part DMP such as to be spaced apart therefrom along the second direction DR2.

FIGS. 8A and 8B are each a plan view of an electronic apparatus ED according to an embodiment of the invention. FIGS. 8A and 8B each schematically illustrate a display panel DP and a circuit board FCB to correspond to those of FIG. 4A. Hereinafter, the invention will be described with reference to FIGS. 8A and 8B. Meanwhile, components which are the same as the components described with reference to FIGS. 1 to 7B will be denoted as the same reference numerals or symbols, and duplicated descriptions will be omitted.

Referring to FIG. 8A, the bank BNP may be omitted in the display panel DP. In this case, an organic film which is most adjacent to a first pad region PA1 or a second pad region PA2, may be a portion of a dam part DMP. Thus, a stepped region GA may overlap an inner side surface of the dam part DMP which faces a display region DP-DA. Since the inner side surface of the dam part DMP includes a plurality of inclined parts having different angles of inclination, a step of the inner side surface may be segmented. Detailed description thereof corresponds to that of the first side surface SF1 (see FIG. 5B) of the bank BNP (see FIG. 5B) described above, and thus duplicated descriptions will be omitted. That is, the inner side surface of the dam part DMP in FIG. 8A may have the inclined structure of the first side surface SF1 described above.

In the plan view, a fan-out line RTL may have a linear shape parallel to the second direction DR2, in the stepped region GA. That is, a third part L3 among first to third parts L1, L2 and L3 of the fan-out line RTL may be provided by a length of the fan-out line RTL which overlaps the stepped region GA. Thus, an overlapping area of the fan-out line RTL and the stepped region GA may be minimized, and an impact according to collision with the dam part DMP during a process of attaching the optical film OTF (see FIG. 6) in the stepped region GA may be minimized.

Referring to FIG. 8B, a plurality of dam parts DMP1 and DMP2 may be provided, and the bank BNP may be omitted in a display panel DP. The dam parts DMP1 and DMP2 may include a first dam part DMP1 as an inner dam and a second dam part DMP2 as an outer dam which are formed spaced apart from each other. In this case, an organic film which is most adjacent to a first pad region PA1 or a second pad region PA2 may be the second dam part DMP2.

A stepped region GA may be formed between the first dam part DMP1 and the second dam part DMP2 and overlap an inner side surface of the second dam part DMP2 which faces a display region DP-DA. Since the inner side surface of the second dam part DMP2 includes a plurality of inclined parts having different angles of inclination, a step of the inner side surface overlapping the stepped region GA may be segmented. Detailed description thereof corresponds to that of the first side surface SF1 (see FIG. 5B) of the bank BNP (see FIG. 5B) described above, and thus duplicated descriptions will be omitted. That is, the inner side surface of the second dam part DMP2 in FIG. 8B may have the inclined structure of the first side surface SF1 described above.

In the plan view, a fan-out line RTL may have a linear shape parallel to the second direction DR2, in the stepped region GA. That is, a third part L3 among first to third parts L1, L2 and L3 of the fan-out line RTL may be provided by a length of the fan-out line RTL which overlaps the stepped region GA. Thus, an overlapping area of the fan-out line RTL and the stepped region GA may be minimized, and an impact according to collision with the dam part DMP during a process of attaching the optical film OTF (see FIG. 6) in the stepped region GA may be minimized.

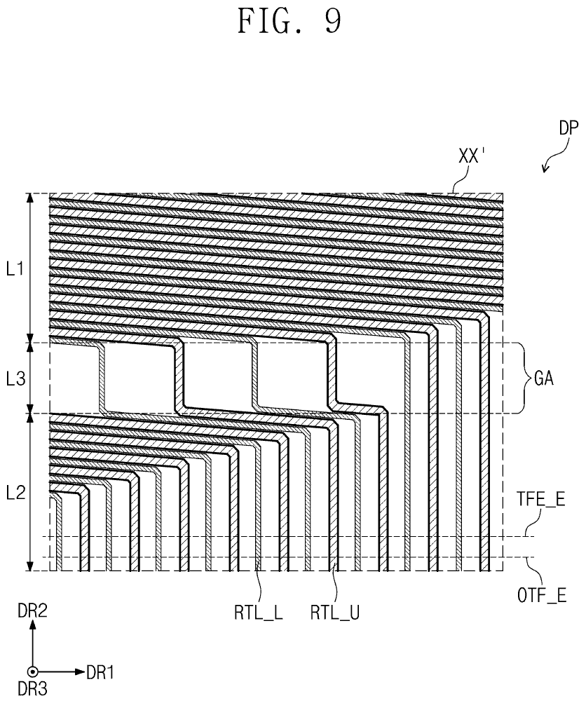

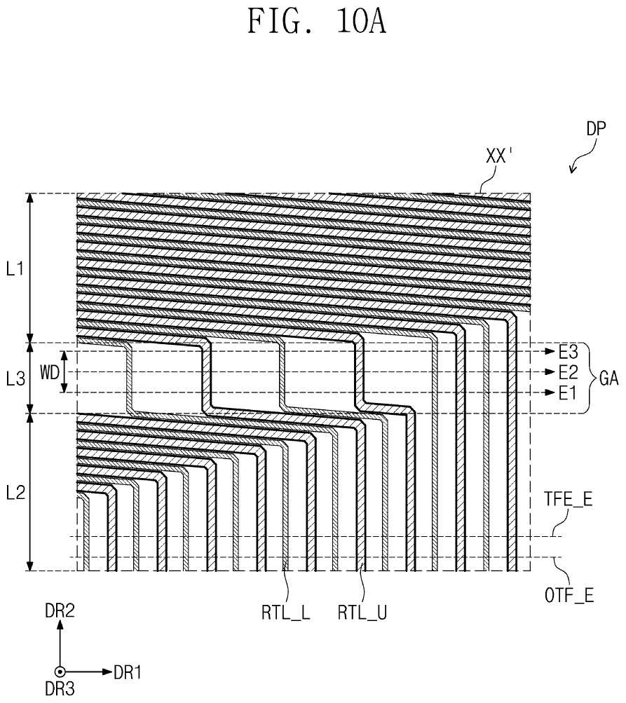

FIG. 9 is a plan view illustrating a partial region of a display panel DP according to an embodiment of the invention. Referring to FIG. 9, a display panel DP may include a first fan-out line RTL_L and a second fan-out line RTL_U which are disposed at different layers among layer disposed on the base layer SUB. The second fan-out line RTL_U as an upper fan-out line may be disposed at a layer above the first fan-out line RTL_L as a lower fan-out line, and at least one insulating layer may be disposed between the first fan-out line RTL_L and the second fan-out line RTL_U.

Each of the first fan-out line RTL_L and the second fan-out line RTL_U may include, with respect to a stepped region GA, a first part L1 disposed between the stepped region GA and a display region DP-DA, a second part L2 disposed between the stepped region GA and the pad PD (see FIG. 4A), and a third part L3 connecting the first part L1 and the second part L2 to each other. The first part L1 and the third part L3 may be inclined or parallel with respect to the second direction DR2, and the third part L3 may be designed to be parallel to the second direction DR2. The third part L3 which crosses the stepped region GA may be designed to have a minimum dimension (or length) in a direction from the display region DP-DA to the pad region PA.

The display panel DP according to this embodiment may include the fan-out lines RTL_U and RTL_L disposed at different layers from each other, and thus a contact, electrical influence, total planar area along the base layer SUB, etc. between the first fan-out line RTL_L and the second fan-out line RTL_U may be minimized. Thus, a planar space, in a plan view, between the first fan-out line RTL_L and the second fan-out line RTL_U may be narrowly formed, which may make fine pitch design of fan-out lines RTL possible and may be advantageous for forming a high-resolution display panel.

In addition, the fan-out lines RTL_U and RTL_L according to the invention may include the third part L3 parallel to the second direction DR2 in the stepped region GA, and thus a route (e.g., a length) passing along the stepped region GA may be minimized. This may substantially amount to minimizing a planar area of the fan-out lines RTL_U and RTL_L overlapping the stepped region GA.

As described above, the stepped region GA may be a region in which collision with a roller may occur during a process of attaching the optical film OTF to the underlying stacked structure of the display panel DP and to which an impact or force according to the collision is transferred. According to the invention, even if the encapsulation layer TFE to which the optical film OTF is attached is damaged, an area (e.g., a planar area) of the fan-out lines RTL_U and RTL_L which are underneath the encapsulation layer TFE and exposed due to the damaged encapsulation layer TFE may be minimized by designing the third part L3 of the fan-out lines RTL_U and RTL_L overlapping the stepped region GA to be parallel to the second direction DR2. Thus, process reliability of the display panel DP may be improved.

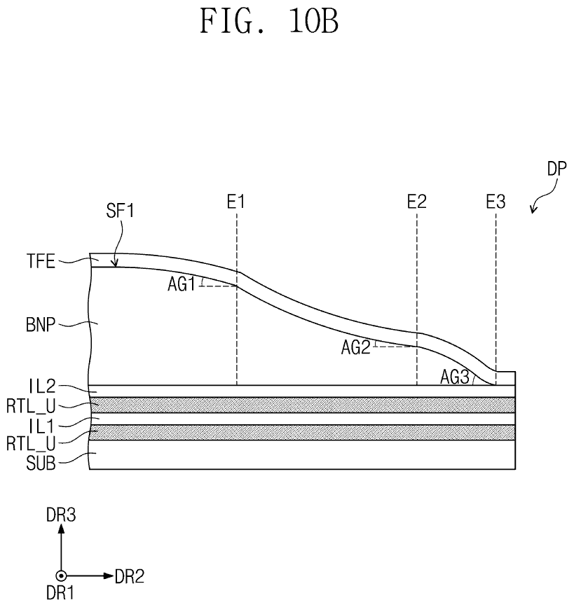

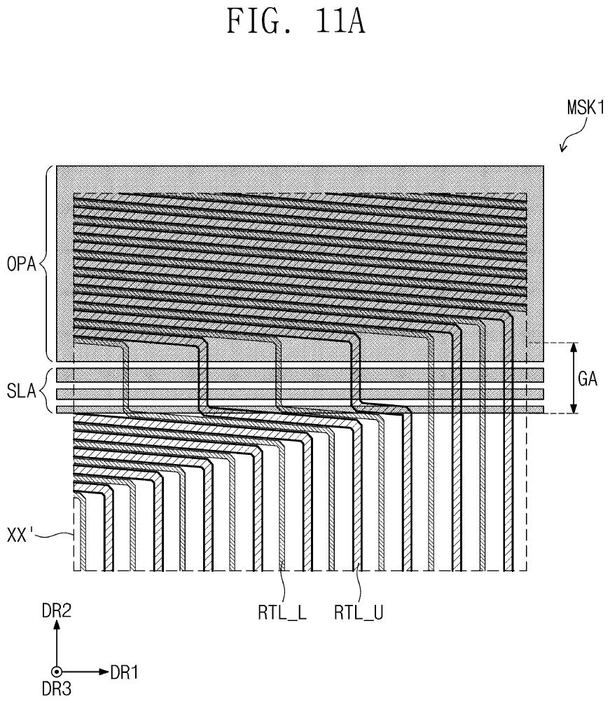

FIG. 10A is a plan view illustrating a portion of a display panel DP according an embodiment of the invention. FIG. 10B is a cross-sectional view, of a display panel DP, illustrating a portion of a region corresponding to that of FIG. 10A. FIG. 10A illustrates a region corresponding to that of FIG. 9, and FIG. 10B schematically illustrates components of the display panel DP. Hereinafter, the invention will be described with reference to FIGS. 10A and 10B. Meanwhile, components which are the same as the components described with reference to FIGS. 1 to 9 will be denoted as the same reference numerals or symbols, and duplicated descriptions will be omitted.

As illustrated in FIG. 10A, each of fan-out lines RTL_U and RTL_L may include a third part L3 parallel to the second direction DR2 in a stepped region GA. FIG. 10A may substantially correspond to FIG. 9, and thus duplicated descriptions will be omitted.

As illustrated in FIG. 10B, a first inorganic layer IL1 may be disposed between a first fan-out line RTL_L and a second fan-out line RTL_U, and the second fan-out line RTL_U may be covered with a second inorganic layer IL2. A bank BNP is illustrated as a single layer for convenience of illustration, and an encapsulation layer TFE may cover the bank BNP and the second inorganic layer IL2. For ease of description, the components illustrated in FIG. 10B may correspond to one of the above-described insulating layers 10, 20, 30, 40, 50, 60, 70, PDL, LIL, OL and UIL or may be partially illustrated, and duplicated descriptions will be omitted.

First to third points E1, E2 and E3 are indicated along a first side surface SF1 of the bank BNP. The first to third points E1, E2 and E3 may be sequentially positioned, in a stepped region GA, in a direction from the pad region PA to the display region DP-DA, that is, toward an end OTF_E of an optical film OTF and an end TFE_E of an encapsulation layer TFE. Each of the end OTF_E of the optical film OTF and the end TFE_E of an encapsulation layer TFE may be an end furthest from the display region DP-DA of the respective layer. The optical film OTF may extend further than the end TFE_E of the encapsulation layer TFE, such as to define an extended portion of the optical film OTF. Here, the extended portion may define the end OTF_E of the optical film OTF.

First to third points E1, E2 and E3 may indicate a change in angle of inclination of the first side surface SF1 relative to an adjacent angle of inclination. In an interval WD from the first point E1 to the third point E3, each of the fan-out lines RTL_L and RTL_U may have a linear shape extending the second direction DR2 in a plan view.

First to third angles of inclination AG1, AG2 and AG3 respectively measured at the first to third points E1, E2 and E3 may be different from each other. In this embodiment, the second angle of inclination AG2 may be the smallest among the first to third angles of inclination AG1, AG2 and AG3, and the third angle of inclination AG3 may be the largest. The third point E3 may be an end of the first side surface SF1, that is an end of the bank BNP.

In addition, an inclination shape of each of the first to third points E1, E2 and E3 may be various. In this embodiment among parts of the bank BNP, an inclined part passing the first point E1 may have a shape of a relatively convex curved surface of which an angle of inclination increases toward the first point E1, an inclined part between the first point E1 and the second point E2 may have a shape of a relatively concave curved surface, and an inclined part between the second point E2 and the third point E3 may have a shape of a convex curved surface again. That is, when the first side surface SF1 includes curved surfaces, the first to third points E1, E2 and E3 may be inflection points at which angles of the first side surface SF1 change.

Meanwhile, an angle of inclination of the first side surface SF1 may increase and then gradually decrease in a direction from the second point E2 to the third point E3. Accordingly, a tail may be formed at an end of the first side surface SF1. Accordingly, a step at the third point E3 connected to or meeting the second inorganic layer IL2 may be minimized, and an impact with the roller RLR occurring during attaching the optical film OTF to the stacked structure may be minimized. The first side surface SF1 according to an embodiment of the invention may include inclined parts having different angles of inclination, and the inclined parts may be provided in various shapes such as a flat surface and a curved surface but are not limited to any one embodiment.

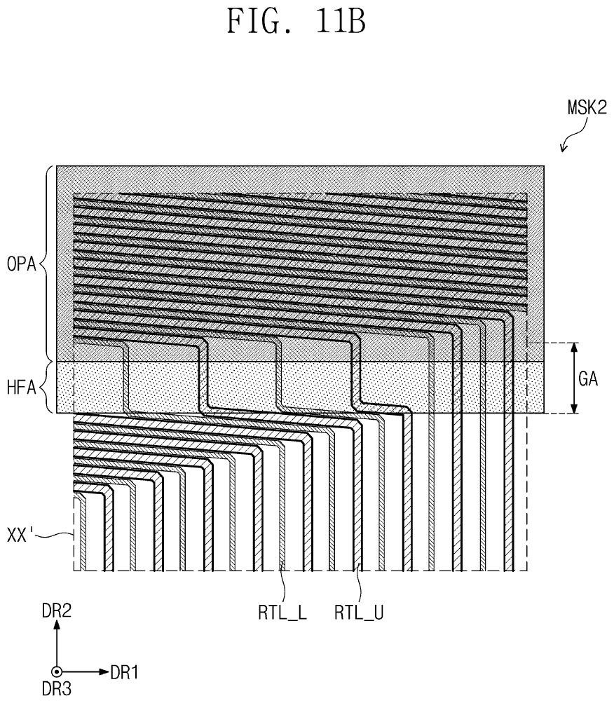

FIGS. 11A and 11B are each a plan view illustrating a process in manufacturing (or providing) a display panel DP according to an embodiment of the invention. FIGS. 11A and 11B each illustrate a planar region corresponding to a region illustrated in FIG. 10A at which an operation of forming a bank BNP is provided. Hereinafter, the invention will be described with reference to FIGS. 11A and 11B. Meanwhile, components which are the same as the components described with reference to FIGS. 1 to 10B will be denoted as the same reference numerals or symbols, and duplicated descriptions will be omitted.

Referring to FIG. 11A, the bank BNP may be formed through a photolithography process using a mask MSK1. The mask MSK1 may include an open region OPA and a slit region SLA. An organic film for forming the bank may be formed on an entire base layer and patterned through the mask MSK1. The organic film described with respect to the method may include one or more of the organic layers described above which form various thickness portions of the bank BNP. The mask MSK1 may be integrally formed with an overall mask for forming organic films which are formed in the display region DP-DA.

The open region OPA may correspond to a region in which the organic film is removed from an underlying preliminary stacked structure. The organic film may be easily removed by exposure dose through the open region OPA. The slit region SLA may be a region including solid portions of the mask MSK1 which are spaced apart from each other with an opening (e.g., slits) therebetween. As a width of a slit in the second direction DR2 is relatively large among a plurality of slits, exposure dose passing through the mask MSK1 may be relatively large. According to this embodiment, an inclined part shape having thicknesses which decrease in an opposite direction of the second direction DR2, that is, in a direction from the pad region PA to the display region DP-DA may be formed by designing the slit region SLA to include the slits of which widths decrease in the opposite direction of the second direction DR2 along a stepped region GA. In addition, a plurality of inclined parts may be easily formed by controlling a space (e.g., opening) between slits, widths of the slits and/or the number of the slits.

Referring to FIG. 11B, a mask MSK2 may include an open region OPA and a half-tone region HFA. In this embodiment, for ease of description, the half-tone region HFA and the open region OPA are illustrated in different shades. The open region OPA may be a full-tone region. Since exposure dose is relatively low in the half-tone region HFA compared to the open region OPA, inclined parts of the bank BNP may be formed by removing only a portion of an underlying organic film.

The bank BNP according to an embodiment of the invention may be formed using various manufacturing methods as long as the first side surface SF1 is formed so as to have various inclined parts, and is not limited to any one embodiment.

A display device DD according to an embodiment may be applied to various electronic apparatuses. An electronic apparatus ED according to an embodiment may include the display device DD described above, and may further include another module or device having an additional function in addition to the display device DD.

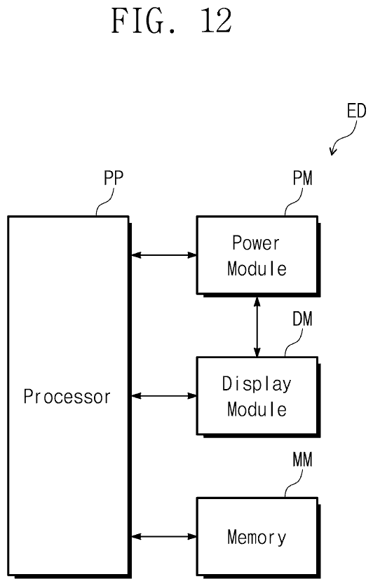

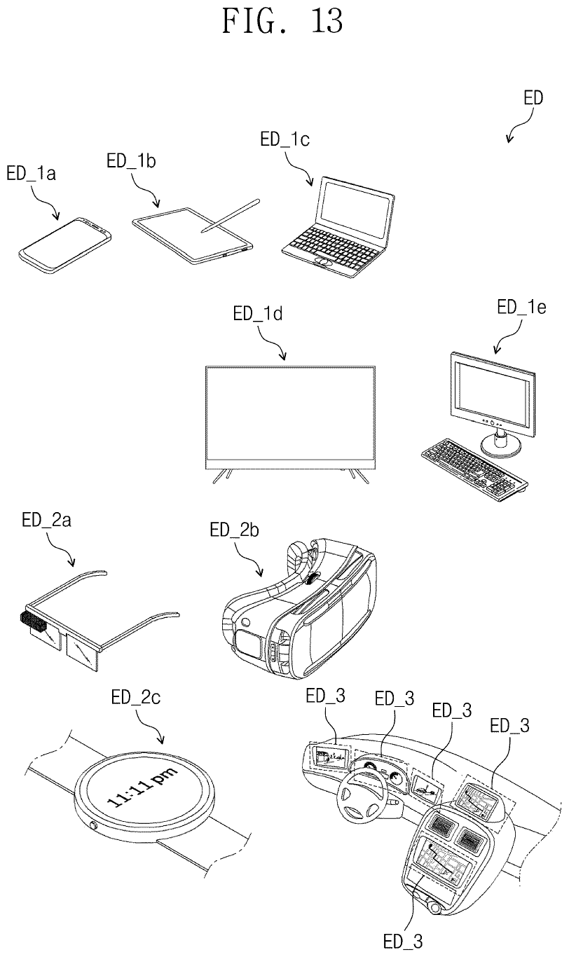

FIG. 12 is a block diagram of an electronic apparatus ED according to an embodiment. Referring to FIG. 12, an electronic apparatus ED according to an embodiment may include a display module DM, a processor PP, a memory MM and a power module PM. The electronic apparatus ED may correspond to the electronic apparatus ED illustrated in FIG. 1.

The processor PP may include at least one among a central processing unit (CPU), an application processor (AP), a graphic processing unit (GPU), a communication processor (CP), an image signal processor (ISP), and a controller. In an embodiment, the processor PP may be divided into two or more in a functional or structural point of view and provided. For example, the processor PP may include a main processor in a form of a first driving chip including a central processing unit, and an auxiliary processor in a form of a second driving chip including a controller which receives an image signal from the main processor and processes the image signal to comply with specifications of interface of the display module DM.

The memory MM may include at least one of a nonvolatile memory and a volatile memory. Data information required for an operation of the processor PP or the display module DM may be stored in the memory MM. When the processor PP executes an application stored in the memory MM, an image data signal and/or an input control signal may be transferred to the display module DM, and the display module DM may process the provided signal and output image information through a display screen.

The power module PM may include a power supply module such as a power adapter or a battery device and a power conversion module which converts power supplied by the power supply module and generates power required for an operation of the electronic apparatus ED. Power conversion using the power conversion module may include DC-DC conversion, AC-DC conversion, and DC-AC conversion, but is not limited thereto.

At least one of components of the electronic apparatus ED described above may be included in a display device DD according to the embodiments described above. In addition, some of individual modules included in functionally one module may be included in the display device DD, and the others may be provided separately from the display device DD. For example, the display device DD may include the display module DM and the auxiliary processor of the processor PP, and the main processor of the processor PP, the memory MM and the power module PM may be provided in a form of another device in the electronic apparatus ED, not the display device. For another example, the power module PM may be provided in the display device DD and supply power to the processor PP and the memory MM provided in the electronic apparatus ED, not the display device DD, and an embodiment of the invention is not limited to the above example.

FIG. 13 illustrates schematic views of electronic apparatuses according to various embodiments.

Referring to FIG. 13, various electronic apparatuses to which a display device DD according to embodiments is applied may include not only an electronic apparatus ED for displaying images, such as a smartphone ED_1a, a tablet personal computer (PC) ED_1b, a laptop computer ED_1c, a television ED_1d, and a desk monitor ED_1e but also a wearable electronic apparatus including a display module DM, such as smart glasses ED_2a, a head-mounted display ED_2b, and a smart watch ED_2c, automotive electronic apparatuses ED_3 including a display module DM, such as a center information display (CID) disposed on an instrument panel, a center fascia, and a dashboard of an automobile, a room mirror display, etc., and the like.

The electronic apparatus ED of FIG. 13 may include the components illustrated in FIG. 12. For example, the smartphone ED_1a may include the display module DM, the processor PP, the memory MM and the power module PM illustrated in FIG. 12. The smartphone ED_1a may further include a communication module and a battery device. Power provided from the battery device may be converted through the power module PM and provided to the processor PP, the memory MM and the display module DM. In an embodiment, a display device applied to the smartphone ED_1a may include the display module DM and may further include the power module PM. The processor PP and the memory MM may be provided in a form of a chip mounted on a mother board which is an external device, but an embodiment of the invention is not limited thereto.

According to the invention, an impact applied to a display panel DP during attaching an optical film OTF may be alleviated. In addition, according to the invention, an area of a signal line like a fan-out line RTL which is exposed to outside the display panel DP owing to an impact occurring during attaching the optical film OTF may be minimized. Thus, a possibility of the signal line being damaged may be reduced. Accordingly, manufacturing process reliability of an electronic apparatus ED may be improved.

In the above, description has been made with reference to embodiments of the invention, but those skilled or of ordinary skill in the art may understand that various modifications and changes may be made to the invention insofar as such modifications and changes do not depart from the spirit and technical scope of the invention set forth in the claims to be described later. Therefore, the technical scope of the invention is not to be limited to the contents stated in the detailed description of the specification, but should be determined by the claims.

What is claimed is:

1. An electronic apparatus comprising:
a base substrate including a display region and a peripheral region which is adjacent to the display region;
a light-emitting element layer in the display region, the light-emitting element layer including a pixel-defining film having an opening defined therein and a light-emitting element which is in the opening;
a driving element layer between the base substrate and the light-emitting element layer, the driving element layer including:
a pixel driving part connected to the light-emitting element,
a signal line connected to the pixel driving part, the signal line including a fan-out line which is in the peripheral region and defines a pad part at the end thereof,
an organic film, and
an inorganic film;
an encapsulation layer on the light-emitting element layer, the encapsulation layer including an inorganic encapsulation layer; and
a bank in the peripheral region, the bank extending along a first direction and spaced apart from the display region in a second direction which crosses the first direction, the bank including:
an organic layer having a first side surface closest to the display region, and
the first side surface including at least two inclined parts adjacent in the second direction and having different angles of inclination in a cross-sectional view, wherein
the peripheral region includes a stepped region defined between the pad part and the display region, the stepped region including the first side surface of the bank, and
a first part of the fan-out line overlaps the stepped region and is parallel to the second direction.

2. The electronic apparatus of claim 1, further comprising a driving chip connected to the pad part.

3. The electronic apparatus of claim 1, further comprising a circuit board connected to the pad part.

4. The electronic apparatus of claim 1, wherein the angle of inclination is less than about 90 degrees.

5. The electronic apparatus of claim 4, wherein the organic layer of the bank is in a same layer as the organic film of the driving element layer or in a same layer as the pixel-defining film.

6. The electronic apparatus of claim 1, further comprising an optical film which is on the encapsulation layer and covers the stepped region, the optical film including an end which is furthest from the display region
wherein the bank overlaps the end of the optical film.

7. The electronic apparatus of claim 6, wherein
the inorganic encapsulation layer covers the stepped region, the inorganic encapsulation layer including an end which is furthest from the display region and
the optical film covers the end of the inorganic encapsulation layer.

8. The electronic apparatus of claim 1, wherein the fan-out line further comprises:
a second part extending from one end of the first part and toward the display region, the second part being inclined with respect to the first part; and
a third part extending from the other end of the first part and toward the pad part, the third part being inclined with respect to the first part.

9. The electronic apparatus of claim 1, wherein the bank has a frame shape surrounding the display region.

10. The electronic apparatus of claim 1, wherein the first side surface of the bank has a curved surface.

11. An electronic apparatus comprising:
a display panel including:
a substrate,
an inorganic layer on the substrate,
a fan-out line between the substrate and the inorganic layer,
a light-emitting element on the inorganic layer, the light-emitting element including an anode, a light-emitting layer and a cathode,
a bank which is on the inorganic layer, overlaps the fan-out line, extends along a first direction, and is spaced apart from the light-emitting element in a second direction crossing the first direction along the substrate,
the bank comprising:
an organic layer having a first side surface facing the light-emitting element along the second direction, and
the first side surface including two inclined parts adjacent in the second direction and having different angles of inclination in a cross-sectional view, and
an encapsulation layer covering the light-emitting element, the encapsulation layer including a first inorganic encapsulation layer, an organic encapsulation layer and a second inorganic encapsulation layer, and
an optical film on the display panel, the optical film including an end which overlaps the bank,
wherein a first part of the fan-out line overlaps the first side surface of the bank and is parallel to the second direction.

12. The electronic apparatus of claim 11, wherein within the first side surface of the bank, each of the angles of inclination is less than about 90 degrees.

13. The electronic apparatus of claim 11, wherein within the bank:
the organic layer is provided in plural to define a plurality of organic layers, and
the first side surface of the bank is defined by respective side surfaces of at least two organic layers among the plurality of organic layers.

14. The electronic apparatus of claim 11, wherein within the bank:
the organic layer is provided in plural to define a plurality of organic layers, and
the first side surface of the bank is defined by any one organic layer among the plurality of organic layers.

15. The electronic apparatus of claim 14, wherein within the bank:
the plurality of organic layers include a first organic layer, a second organic layer and a third organic layer which are sequentially stacked,
the second organic layer covers the first organic layer,
the third organic layer is spaced apart from the first organic layer and covers the second organic layer, and
the first side surface of the bank is defined by the third organic layer.

16. The electronic apparatus of claim 14, wherein within the bank:
the plurality of organic layers include a first organic layer, a second organic layer and a third organic layer which are sequentially stacked,
the second organic layer exposes a side surface of the first organic layer, and
the third organic layer covers the side surface of the first organic layer which is exposed.

17. The electronic apparatus of claim 11, wherein
the bank further comprises a second side surface opposite to the first side surface along the second direction, and
the second side surface has a shape in the cross-sectional view which is different from a shape of the first side surface.

18. The electronic apparatus of claim 11, wherein at a location overlapping the fan-out line, at least one of the first inorganic encapsulation layer and the second inorganic encapsulation layer is in contact with the inorganic layer.

19. The electronic apparatus of claim 11, wherein the fan-out line further comprises a second part which extends from one end of the first part and is inclined with respect to the first direction and the second direction in a plane defined by the first direction and the second direction which cross each other.

20. The electronic apparatus of claim 19, wherein the fan-out line further comprises a third part which extends from the other end of the first part and overlaps the end of the optical film.
